(19) United States
(12) Patent Application Publication
(10) Pub. No.: US 2022/0029118 A1
(43) Pub. Date: Jan. 27, 2022

(54) PEROVSKITE LIGHT-EMITTING DEVICE COMPRISING PASSIVATION LAYER AND MANUFACTURING METHOD THEREFOR

(71) Applicant: SEOUL NATIONAL UNIVERSITY R&DB FOUNDATION, Seoul (KR)

(72) Inventors: Tae-Woo LEE, Seoul (KR); Young-Hoon KIM, Seoul (KR); Sungjin KIM, Seoul (KR); Seung-Hyeon JO, Seoul (KR); Jin Woo PARK, Seoul (KR)

(21) Appl. No.: 17/268,461

(22) PCT Filed: Dec. 31, 2019
(86) PCT No.: PCT/KR2019/018761

§ 371 Date: Jun. 15, 2021

(30) Foreign Application Priority Data
Apr. 16, 2019 (KR) 10-2019-0044532

(51) Int. Cl. H01L 51/50; H01L 33/44; H01L 33/00; H01L 51/56

(52) U.S. Cl. CPC H01L 51/50; H01L 33/44; H01L 33/0095; H01L 33/18; H01L 2251/558; H01L 51/5012; H01L 51/56

(57) ABSTRACT

The present inventive concept relates to a perovskite light emitting device, and more particularly, to a perovskite light emitting device in which defects of the perovskite thin film are reduced by forming a passivation layer on the perovskite thin film. The passivation layer in the perovskite light emitting device according to the present inventive concept is formed on the top of the perovskite thin film to remove the defects of the perovskite nanocrystal particles and to solve the charge imbalance in the device, so the maximum efficiency and maximum luminance of a light emitting device including the perovskite thin film are improved.

### TECHNICAL FIELD

The present inventive concept relates to a perovskite light-emitting device, and more particularly, to a perovskite light-emitting device in which defects of the perovskite thin film are reduced by a passivation layer formed on perovskite thin film.

### BACKGROUND ART

The current megatrend in the display market is moving to a high-efficiency, high-resolution display that aims to achieve high-purity and natural colors in addition to the existing high-efficiency, high-resolution displays. From this point of view, an organic light-emitting-diode (OLED) device based on an organic light emitter has made a leap forward, and an inorganic quantum dot LED with improved color purity is being actively researched and developed as another alternative. However, both the organic and the inorganic quantum dot emitters have inherent limitations in terms of materials.

Existing organic light emitters have the advantage of high efficiency, but their color purity is poor due to a wide spectrum. And, although they have the advantage of being high efficiency, their color purity is not good because the spectrum is wide. In addition, inorganic quantum dot emitters have been known to have good color purity, but because they emit light with quantum confinement effect or quantum size effect, they are mainly of diameters of 10 nm or less, the luminous color changes according to the size of the nanocrystalline particles, but there is a problem in that the color purity decreases because it is difficult to control the quantum dot size to be uniform as it goes toward the blue color. Moreover, since the inorganic quantum dots have a very deep valence band, there is a problem in that hole injection is difficult because the hole injection barrier from the organic hole injection layer is very large. In addition, the organic light emitters and the inorganic quantum dot light emitters have a disadvantage of being expensive. Accordingly, there is a need for a new type of organic-inorganic hybrid light emitters that compensates for the shortcomings of the organic and the inorganic quantum dot emitters and maintains their advantages.

On the other hand, organic-inorganic hybrid materials have the advantages of low manufacturing costs, simple manufacturing and device manufacturing processes, and the advantages of organic materials that are easy to control optical and electrical properties, and of inorganic materials having high charge mobility and mechanical and thermal stability. It is in the spotlight academically and industrially because you can have both advantages of organic and inorganic emitters.

Among them, the metal halide perovskite material has a high color purity, simple color control, and low synthesis cost, so the possibility of development as a light emitter is very high. In addition, since it has a high color purity (Full width at half maximum (FWHM)≈20 nm), it is possible to implement a light-emitting device closer to natural color.

A material having a conventional perovskite structure (ABX₃) is an inorganic metal oxide.

These inorganic metal oxides are generally oxides, and cations of metals such as Ti, Sr, Ca, Cs, Ba, Y, Gd, La, Fe, and Mn having different sizes (alkali metals, alkaline earth metals, transition metals, and lanthanum groups) are located at the A and B sites, and oxygen anions are located at the X site, and the metal cations at the B site are 6-fold coordination with the oxygen anions at the X site. It is a material that is bound in the form of a corner-sharing octahedron. Examples thereof include SrFeO₃, LaMnO₃, and CaFeO₃.

In contrast, metal halide perovskite has an organic ammonium (RNH₃) cation or metal cation located at the A site in the ABX₃ structure, and a halide anion (Cl⁻, Br⁻, I⁻) at the X site. As a result, a metal halide perovskite material is formed, so the composition is completely different from the inorganic metal oxide perovskite material.

In addition, the properties of the material are also changed according to the difference between these constituent materials. Inorganic metal oxide perovskite typically exhibits properties such as superconductivity, ferroelectricity, and colossal magnetoresistance, and therefore, research has been generally applied to sensors, fuel cells, and memory devices. As an example, yttrium barium copper oxide has superconducting or insulating properties depending on the oxygen contents.

On the other hand, metal halide perovskite is similar to lamellar crystal structure because the organic or alkali metal plane and the inorganic plane are stacked alternately, so the excitons can be confined within the inorganic plane of the crystal. Therefore, since the properties of the metal halide perovskite are essentially determined by the crystal structure rather than the size of the material, the metal halide perovskite itself can be an ideal light emitter that emits light of very high color purity.

Even among metal halide perovskite materials, organic-inorganic hybrid perovskite (i.e., organometal halide perovskite), if organic ammonium (A) contains a chromophore (mainly including a conjugated structure) which have a smaller band gap than the central metal-halogen crystal structure (BX₃), light of high color purity cannot be emitted, and the full-width-at-half-maximum (FWHM) of the emission spectrum becomes wider than 50 nm, making it unsuitable as a light-emitting layer. Therefore, in this case, it is not very suitable for the high color purity emitters emphasized in this patent. Therefore, in order to make high-color-purity light emitters, it is important that organic ammonium does not contain a chromophore and that light emission occurs in an inorganic lattice composed of a central metal-halogen element. In other words, this patent focuses on the development of high color purity and high efficiency light emitters that emit light that originates from an inorganic lattice.

For example, Korean Published Patent No. 10-2001-0015084 (2001.02.26.) discloses an electroluminescent device using a dye-containing organic-inorganic hybrid material as a light-emitting layer by forming a thin film instead of particles. It does not emit light from the perovskite lattice structure.

However, since metal halide perovskite has small exciton binding energy, it is possible to emit light at low temperatures, but at room temperature, excitons do not undergo light emission due to thermal ionization and delocalization of charge carriers: this is a fundamental problem. In addition, when free charges recombine to form excitons, there is a problem in that excitons are quenched by a layer having a high conductivity adjacent to them, and thus light emission cannot occur.

Perovskite nanocrystal particles with improved properties that can be applied to various electronic devices show improved luminescence efficiency by constraining excitons to small size crystal. In addition, even a bulk polycrystalline film having very small grain size may exhibit improved luminescence efficiency through exciton confinement. However, the perovskite emitting layer shows relatively low luminescence efficiency due to the presence of surface defects and shows low luminescence efficiency due to charge carrier imbalance in the light-emitting device.

Accordingly, there is a need for a method capable of eliminating defects in a perovskite thin film and eliminating charge imbalance in a light-emitting device.

### DISCLOSURE

### Technical Problem

A first technical objective to be achieved by the present inventive concept is to provide light-emitting device having a passivation layer capable of reducing defects on a perovskite thin film and eliminating charge imbalance.

Further, a second technical objective to be achieved by the present inventive concept is to provide a method for manufacturing the light-emitting device including the passivation layer.

### Technical Solution

To achieve the above-described first technical objective, the present inventive concept provides a perovskite light-emitting device comprising substrate, a first electrode on the substrate, a perovskite thin film positioned on the first electrode, a passivation layer positioned on the perovskite thin film and having at least one compound of the following Chemical Formulas 1 to 4, and a second electrode positioned on the passivation layer.

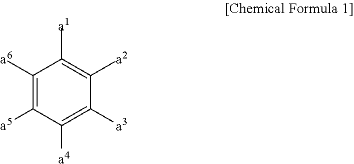

in Chemical Formula 1, a1 to a6 are H, CH₃, or CH₂X, wherein at least three of a1 to a6 are CH₂X, and X is a halogen element,

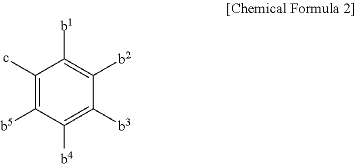

in Formula 2, b1 to b5 is halogen element, c is

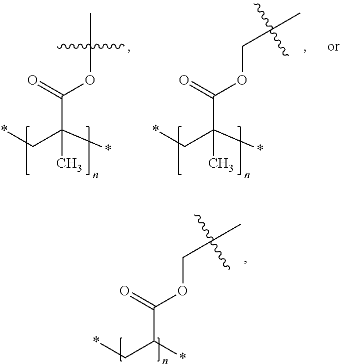

and n is integer 1 to 100,

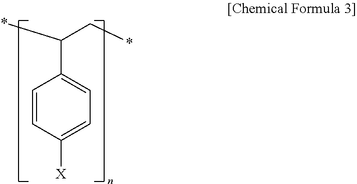

in Chemical Formula 3, X is halogen element, and n is integer 1 to 100,

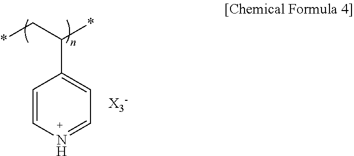

in Chemical Formula 4, X is halogen element, and n is integer 1 to 100.

Furthermore, the passivation layer may have compounds at least one selected from the group of (1,3,5-tris(bromomethyl)benzene), 2,4,6-tris(bromomethyl)mesitylene (TB MM), 1,2,4,5-tetrakis(bromomethyl)benzene, hexakis(bromomethyl)benzene, poly(pentabromophenyl methacrylate), poly(pentabromobenzyl methacrylate), poly(pentabromobenzyl acrylate), poly (4-bromostyrene) and poly(4-vinylpyridinium tribromide).

It is preferable that the passivation layer is a thickness of 1 nm to 100 nm.

It is preferable that the perovskite light-emitting device is a light-emitting diode, a light-emitting transistor, a laser, or a polarized light-emitting device.

It is preferable that the perovskite light-emitting device of further comprises a hole injection layer or an electron transport layer between the first electrode and the perovskite thin film, or between the passivation layer and the second electrode, and the hole injection layer is positioned between the first electrode and the perovskite thin film, and the electron transport layer is positioned between the passivation layer and the second electrode.

To achieve the above-described second technical objective, the present inventive concept provides a method of manufacturing a perovskite light-emitting device, the method having steps of forming a first electrode on a substrate, forming a perovskite thin film on the first electrode, forming a passivation layer having at least one compound of the above described Chemical Formulas 1 to 4 on the perovskite thin film, and a step of forming a second electrode on the passivation layer.

Furthermore, the method of manufacturing a perovskite light-emitting device may have steps of forming a first electrode on a substrate, forming a hole injection layer on the first electrode, forming a perovskite thin film on the hole injection layer, forming a passivation layer having at least one compound of the above described Chemical Formulas 1 to 4 on the perovskite thin film, and forming a second electrode on the passivation layer.

It is preferable that the passivation layer has compound at least one selected from the group of (1,3,5-tris(bromomethyl)benzene), 2,4,6-tris(bromomethyl)mesitylene (TBMM), 1,2,4,5-tetrakis(bromomethyl)benzene, hexakis(bromomethyl)benzene, poly(pentabromophenyl methacrylate), poly(pentabromobenzyl methacrylate), poly(pentabromobenzyl acrylate), poly(4-bromostyrene) and poly(4-vinylpyridinium tribromide).

It is preferable that the passivation layer has a thickness of 1 nm to 100 nm.

Furthermore, the passivation layer may be formed by performing spin coating, bar coating, spray coating, slot die coating, gravure coating, blade coating, screen printing, nozzle printing, inkjet printing, electrohydrodynamic jet printing, electrospray or electrospinning.

Furthermore, the perovskite may have a structure of ABX₃, A₂BX₄, A₃BX₅, A₄BX₆, ABX₄ or Aₙ₋₁PbₙX₃ₙ₋₁ (n is an integer between 2 and 6), the A includes an organic ammonium ion, an organic amidinium ion, an organic phosphonium ion, an alkali metal ion, or a derivative thereof, the B includes a transition metal, a rare earth metal, an alkaline earth metal, an organic substance, an inorganic substance, ammonium, a derivative thereof, or a combination thereof, and the X is a halogen ion or a combination of different halogen ions.

The perovskite thin film may be a bulk polycrystalline thin film or a thin film made of nanocrystal particles, and the nanocrystal particles may have a core-shell structure or a structure having a gradient composition.

### Advantageous Effects

The passivation layer in the perovskite light-emitting device according to the present inventive concept is formed on the perovskite thin film to remove defects at the perovskite nanocrystal particles and to eliminate charge imbalance in the light-emitting device, thereby it improves the efficiency and luminance of a light-emitting device including the perovskite thin film.

The technical effects of the invention are not limited to those mentioned above, and other technical effects that are not mentioned will be clearly understood by those skilled in the art from the following description.

### DESCRIPTION OF DRAWINGS

FIG. 1 is a schematic diagram showing a perovskite light-emitting device according to an embodiment of the present inventive concept.

FIG. 2 is a schematic diagram of the crystal structure of the metal halide perovskite constituting the perovskite thin film in a perovskite light-emitting device according to an embodiment of the present inventive concept.

FIG. 3 is a schematic diagram showing the difference between a perovskite bulk thin film and perovskite nanocrystal particles according to an embodiment of the present inventive concept.

FIG. 4 is a schematic diagram showing a metal halide perovskite nanocrystal particle as a light-emitter constituting a perovskite thin film in a perovskite light-emitting device according to an embodiment of the present inventive concept.

FIG. 5 is a schematic diagram showing a method of manufacturing an organic-inorganic perovskite nanocrystal particle constituting the perovskite thin film in a perovskite light-emitting device according to an embodiment of the present inventive concept.

FIG. 6 is a schematic diagram and an energy band diagram of a perovskite nanocrystal particle according to an embodiment of the present inventive concept.

FIG. 7 is a schematic diagram showing a method of manufacturing core-shell structured organic-inorganic perovskite nanocrystal particle constituting the perovskite thin film in a perovskite light-emitting device according to an embodiment of the present inventive concept.

FIG. 8 is a schematic diagram showing an organic-inorganic perovskite nanocrystal particle having a gradient composition structure constituting the perovskite thin film in a perovskite light-emitting device according to an embodiment of the present inventive concept.

FIG. 9 is a schematic diagram showing an organic-inorganic perovskite nanocrystal particle having a gradient composition constituting a perovskite thin film and an energy band diagram thereof in a perovskite light-emitting device according to an embodiment of the present inventive concept.

FIG. 10 is a schematic diagram showing doped perovskite nanocrystal particles constituting a perovskite thin film and an energy band diagram thereof in a perovskite light-emitting device according to an embodiment of the present inventive concept.

FIG. 11 is a schematic diagram of a perovskite light-emitting device according to an embodiment of the present inventive concept.

FIG. 12 is a graph showing transient photoluminescence and steady-state photoluminescence before and after coating a TBMM thin film as a passivation layer on the perovskite thin film of metal halide perovskite nanocrystal particles.

FIG. 13 shows an X-ray photoelectron spectrum (XPS) before and after coating a TBMM thin film as a passivation layer on the perovskite thin firm of the metal halide perovskite nanocrystal particles.

FIG. 14 is a graph showing the hole current density and electron current density before and after coating the TBMM thin film as a passivation layer formed on perovskite thin film of metal halide perovskite nanocrystal particle in a hole-only device and an electron-only device among perovskite light-emitting devices according to an embodiment of the present inventive concept.

FIG. 15 is a graph showing capacitance-voltage characteristics before and after coating a TBMM thin film as a passivation layer on perovskite thin film of metal halide perovskite nanocrystal particle in a perovskite light-emitting device according to an embodiment of the present inventive concept.

FIG. 16 is a graph showing luminescence efficiency characteristics before and after coating a TBMM thin film as a passivation layer on perovskite thin film of a metal halide perovskite nanocrystal particle in a perovskite light-emitting device according to an embodiment of the present inventive concept.

### DETAILED DESCRIPTION

Hereinafter, exemplary embodiments of the present inventive concept will be described in detail with reference to the accompanying drawings.

While the present inventive concept allows various modifications and variations, specific embodiments thereof are illustrated and illustrated in the drawings and will be described in detail below. However, it is not intended to limit the invention to the particular form disclosed, but rather the invention includes all modifications, equivalents, and substitutions consistent with the spirit of the invention as defined by the claims.

When an element such as a layer, region or substrate is referred to as being “on” another component, it will be understood that it may exist directly on the other element or there may be intermediate elements between them.

Although terms such as first, second, etc. may be used to describe various elements, components, regions, layers and/or regions, these elements, components, regions, layers and/or It will be understood that regions should not be limited by these terms.

The present inventive concept provides a perovskite light-emitting device comprising a passivation layer.

Here, the light-emitting device refers to a device that converts an electronic signal into light, and it may include a device for emitting light such as a light-emitting diode, a light-emitting transistor, a laser, or a polarized light-emitting device.

The perovskite light-emitting device according to the present inventive concept includes a perovskite thin film as a light-emitting layer, and a passivation layer is formed on the perovskite thin film.

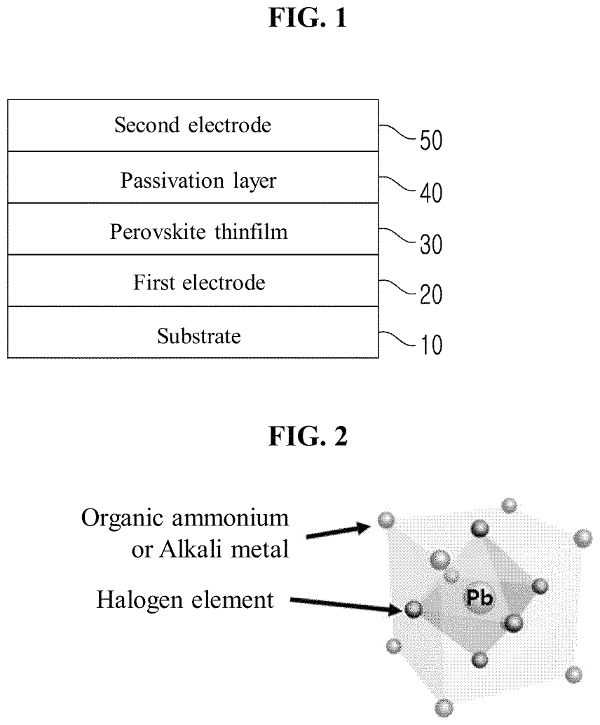

FIG. 1 is a schematic diagram showing a perovskite light-emitting device according to an embodiment of the present inventive concept.

Referring to FIG. 1, the perovskite light-emitting device according to the present inventive concept includes a substrate 10, a first electrode 20, a perovskite thin film 30, a passivation layer 40, and a second electrode 50.

The substrate 10 serves as a support for the light-emitting device and is made of a material having a transparent property. In addition, the substrate 10 may be made of a flexible material and a hard material, but it is more preferable that the substrate 10 is made of a flexible material. As a material of the substrate 10, transparent glass, ceramics materials, a polymer material such as polycarbonate (PC), polyethylene terephthalate (PET), polyethylene naphthalate (PEN), polyimide (PI), or polypropylene (PP). However, the present inventive concept is not limited thereto, and the substrate 10 may be a metal substrate capable of light reflection.

A first electrode 20 may be positioned on the substrate.

The first electrode 20 is an electrode (anode) into which holes are injected and is made of a material having a conductive property. The material constituting the first electrode 20 may be a conductive metal oxide, a metal, a metal alloy, or a carbon material. The conductive metal oxides may include indium tin oxide (ITO), fluorine tin oxide (FTO), antimony tin oxide (ATO), fluorinated tin oxide (FTO), SnO₂, ZnO, or a combination thereof. The metal or metal alloy suitable as anodes may be Au or CuI. The carbon material may be graphite, graphene, or carbon nanotubes.

If the light-emitting device is a light-emitting diode and a conductive polymer is used as the first electrode, a perovskite thin film may be directly formed as a light-emitting layer on the first electrode without additional deposition of a hole injection layer. On the other hand, when an electrode other than a conductive polymer is used as the first electrode 20, it may be necessary to introduce a hole injection layer on the first electrode 20.

Subsequently, a perovskite thin film 30 may be positioned on the first electrode 20.

The perovskite thin film 30 serves as a light-emitting layer in the light-emitting device of the present inventive concept. The perovskite thin film 30 may be made of organic-inorganic hybrid perovskite or inorganic metal halide perovskite, and has a nanocrystal structure of FIG. 2.

FIG. 2 is a structure of a metal halide perovskite nanocrystal according to an embodiment of the present inventive concept.

FIG. 2 shows the structures of organic-inorganic hybrid perovskite nanocrystals and inorganic metal halide perovskite nanocrystals together.

Referring to FIG. 2, the organic-inorganic hybrid perovskite nanocrystal has a center metal in the center, and six inorganic halide materials (X) are located on all surfaces of the hexahedron in a face centered cubic (FCC) structure, and 8 organic ammoniums (OAs) are located at all vertices of the hexahedron of a body centered cubic (BCC) structure. Pb is shown as an example of the center metal.

In addition, the inorganic metal halide perovskite nanocrystal has a center metal in the center, and has six inorganic halide substances (X) are located on all surfaces of the hexahedron in a face centered cubic (FCC), and 8 alkali metals are located at all vertices of the hexahedron in the body centered cubic (BCC) structure. Pb is shown as an example of the center metal.

All planes of the hexahedron form 90° angle between adjacent planes and include not only a cubic structure in which horizontal length, vertical length, and height are all the same, but also a tetragonal structure in which horizontal length and vertical length are same but height is different.

A two-dimensional structure according to the present inventive concept may have a center metal in the center in a face centered cubic structure, halides located on all surfaces of a hexahedron, and organic ammoniums located at all vertices of the cube in a body centered cubic structure. As a hybrid perovskite nanocrystal structure, the horizontal and vertical lengths are the same, but the height may have length of 1.5 times or longer than the horizontal and vertical lengths.

The perovskite thin film may be made of a bulk polycrystal or nanocrystal particles.

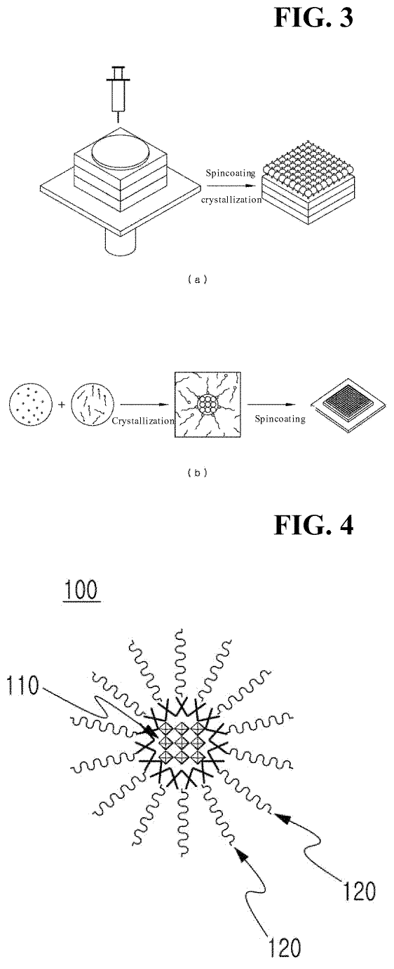

FIG. 3 is a schematic diagram showing the difference between a perovskite bulk thin film and perovskite nanocrystal particles according to an embodiment of the present inventive concept.

As shown in FIG. 3(a), the perovskite bulk thin film is crystallized and coating of the perovskite bulk thin film is simultaneously performed by evaporating the solvent in the spin coating process of the transparent ion-type perovskite precursor. Therefore, since the perovskite bulk thin film is greatly affected by thermodynamic parameters such as temperature and surface energy during the formation process, the perovskite bulk thin film is composed of very irregular grains of several hundred nm to several mm which may include large three-dimensional or two-dimensional polycrystals.

However, as shown in FIG. 3(b), the perovskite nanocrystal particles are firstly formed by crystallization as particles having a size of nm in a colloidal solution, and then the perovskite nanocrystal particles are stably dispersed in the solution using an organic ligand. Since perovskite nanocrystal particles are in a state where crystallization is terminated in the solution, when a thin film is formed through coating, there is no further growth of crystals and is not affected by the coating conditions, so that the perovskite thin film can be formed and has thickness of several nm level that maintains high luminescence efficiency.

FIG. 4 is a schematic diagram showing a metal halide perovskite nanocrystal particle as a light-emitter constituting a perovskite thin film in a perovskite light-emitting device according to an embodiment of the present inventive concept.

On the other hand, an organic-inorganic perovskite nanocrystal particle is shown in FIG. 4, and inorganic metal halide perovskite nanocrystal particles according to an embodiment of the present inventive concept is same with the organic-inorganic hybrid perovskite nanocrystal particles except that the A site is an alkali metal instead of organic ammonium. The alkali metal of the alkali metal of the A site may be, for example, Na, K, Rb, Cs, or Fr.

Therefore, an organic-inorganic hybrid perovskite nanocrystal particle will be described as an example.

Referring to FIG. 4, the organic-inorganic hybrid perovskite nanocrystal particle 100 according to the present inventive concept may include an organic-inorganic perovskite 110 that can be dispersed in an organic solvent. The organic solvent may be a polar solvent or a non-polar solvent.

For example, the polar solvent includes dimethylformamide, gamma butyrolactone, N-methylpyrrolidone or dimethylsulfoxide, and the nonpolar solvent may include dichloroethylene, trichloroethylene, chloroform, chlorobenzene, dichlorobenzene, styrene, dimethylformamide, dimethylsulfoxide, xylene, toluene, cyclohexene or isopropyl alcohol.

In addition, the perovskite nanocrystal structure 100 may have a spherical shape, a cylinder shape, an elliptical cylinder shape, or a polygonal column shape.

In addition, the size of the organic-inorganic perovskite 110 may be 1 nm to 10 μm or less. Preferably 1 nm, 3 nm, 5 nm, 6 nm, 7 nm, 8 nm, 9 nm, 10 nm, 11 nm, 12 nm, 13 nm, 15 nm, 16 nm, 17 nm, 20 nm, 25 nm, 30 nm, 35 nm, 40 nm, 50 nm, 60 nm, 70 nm, 80 nm, 90 nm, 100 nm, 200 nm, 300 nm, 400 nm, 500 nm, 700 nm, 900 nm, 1 μm, 2 μm, 5 μm or 10 μm. Meanwhile, the size of the organic-inorganic perovskite 110 refers to a size that does not take into account the length of a ligand to be described later, that is, the size of the remaining portions excluding the ligand.

For example, when the organic-inorganic perovskite 110 are spherical, the diameter of the perovskite may be 1 nm to 30 nm.

In addition, the band gap energy of the perovskite may be 1 eV to 5 eV.

Accordingly, since the energy band gap is determined according to the constituent material or crystal structure of the nanocrystal particles, light having a wavelength of 200 nm to 1300 nm may be emitted by controlling the constituent material of the nanocrystal particles.

Such an organic-inorganic perovskite 110 may include a structure of ABX₃, A₂BX, ABX₄ or Aₙ₋₁BₙX₃ₙ₊₁ (n is an integer between 2 and 6), wherein A is an amidinium group organic material or an organic ammonium material, B is a metal, and X may be a halogen element.

For example, the amidinium group organic material is formamidinium (NH₂CH═NH⁺), acetamidinium (NH₂C(CH)═NH₂⁺) or guanidinium (NHC(NH)═NH⁺), and the organic ammonium material is (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂ (n is an integer of 1 or more, x is an integer of 1 or more). R of the organic ammonium material means an alkyl group.

B may be a divalent transition metal, a rare earth metal, an alkaline earth metal, Pb, Sn, Ge, Ga, In, Al, Sb, Bi, Po, or a combination thereof. The rare earth metal may be Ge, Sn, Pb, Eu, or Yb, for example. Further, the alkaline earth metal may be, for example, Ca or Sr. In addition, X may be Cl, Br, I, or a combination thereof.

Meanwhile, a plurality of organic ligands 120 surrounding the surface of the organic-inorganic perovskite 110 may be further included.

The organic ligand may include an alkyl halide or a carboxylic acid.

The alkyl halide may be an alkyl-X structure. The halogen element corresponding to X may include Cl, Br, or I. In addition, the alkyl includes an acyclic alkyl having a structure of CₙH₂ₙ₊₁, a primary alcohol having a structure such as CₙH₂ₙ₊₁OH, a secondary alcohol, and a tertiary alcohol, alkylamine having a structure of alkyl-N (ex. Hexadecyl amine, 9-Octadecenylamine 1-Amino-9-octadecene (C₁₉H₃₇N)), p-substituted aniline, phenyl ammonium or fluorine ammonium.

The carboxylic acid is 4,4′-azobis (4-cyanovaleric acid), acetic acid, 5-aminosalicylic acid, acrylic acid, 1-aspentic acid, 6-bromohexanoic acid, bromoacetic acid, dichloro acetic acid, ethylenediaminetetraacetic acid, isobutyric acid, itaconic acid, maleic acid, r-maleimidobutyric acid, 1-malic acid, 4-nitrobenzoic acid, 1-pyrenecarboxylic acid or oleic acid.

The organic-inorganic perovskite nanocrystal particles according to the present inventive concept can provide perovskite having various band gaps according to substitution of halogen elements.

For example, an organic-inorganic perovskite including a CH₃NH₃PbCl₃ may have a band gap energy of about 3.1 eV. In addition, the organic-inorganic perovskite including the CH₃NH₃PbBr₃ may have a band gap energy of about 2.3 eV. In addition, the organic-inorganic perovskite including the CH₃NH₃PbI₃ may have a band gap energy of about 1.5 eV.

In addition, the organic-inorganic perovskite nanocrystal particles according to the present inventive concept can provide organic-inorganic perovskites having various band gaps according to substitution of organic elements.

For example, when n=4 in (CₙH₂ₙ₊₁NH₃)₂PbBr₄, organic-inorganic perovskite having a band gap of about 3.5 eV can be provided. In addition, when n=5, organic-inorganic perovskite having a band gap of about 3.33 eV can be provided. In addition, when n=7, organic-inorganic perovskite having a band gap of about 3.34 eV can be provided. In addition, when n=12, organic-inorganic perovskite having a band gap of about 3.52 eV can be provided. In addition, the organic-inorganic perovskite nanocrystal particles according to the present inventive concept can provide organic-inorganic perovskites having various band gaps according to the substitution of a central metal.

For example, an organic-inorganic perovskite including a CH₃NH₃PbI₃ organic-inorganic perovskite may have a band gap energy of about 1.5 eV. In addition, the organic-inorganic perovskites including the CH₃NH₃Sn_{0.3}Pb_{0.7}I may have a band gap energy of about 1.31 eV. In addition, the organic-inorganic perovskite including the CH₃NH₃Sn_{0.5}Pb_{0.5}I may have a band gap energy of about 1.28 eV. In addition, the organic-inorganic perovskite including the CH₃NH₃Sn_{0.7}Pb_{0.3}I₃ may have a band gap energy of about 1.23 eV. In addition, the organic-inorganic perovskite including the CH₃NH₃Sn_{0.9}Pb_{0.1}I₃ may have a band gap energy of about 1.18 eV. In addition, the organic-inorganic perovskite including the CH₃NH₃SnI₃ may have a band gap energy of about 1.1 eV. In addition, the organic-inorganic perovskite including the CH₃NH₃PbₓSn₁₋ₓBr₃ may have a band gap energy of 1.9 eV to 2.3 eV. In addition, the organic-inorganic perovskite including the CH₃NH₃PbₓSn₁₋ₓCl₃ may have a band gap energy of 2.7 eV to 3.1 eV.

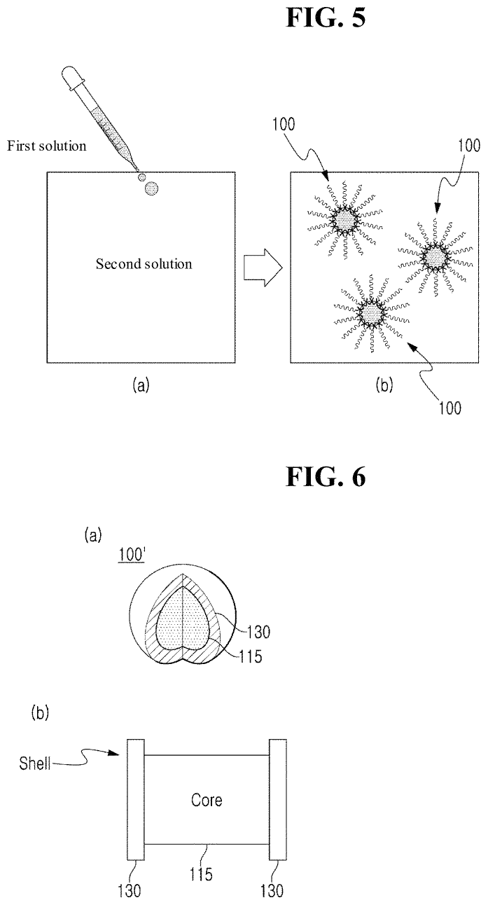

FIG. 5 is a schematic diagram showing a method of manufacturing an organic-inorganic perovskite nanocrystal particle according to an embodiment of the present inventive concept. Referring to FIG. 5 (a), the method of manufacturing the organic-inorganic perovskite nanocrystal particle has step of preparing a first solution in which the organic-inorganic perovskite is dissolved in a polar solvent and second solution in which a surfactant is dissolved in a non-polar solvent, and step of mixing the first solution with the second solution to form the perovskite nanocrystal particles.

First, a first solution in which an organic-inorganic perovskite is dissolved in a polar solvent and a second solution in which a surfactant is dissolved in a non-polar solvent are prepared.

The polar solvent of the first solution may include dimethylformamide, gamma butyrolactone or N-methylpyrrolidone, dimethylsulfoxide, but is not limited thereto. In addition, the organic-inorganic perovskite of the first solution may be a material having a three-dimensional crystal structure, a two-dimensional crystal structure, a one-dimensional crystal structure, or a zero-dimensional crystal structure.

For example, the organic-inorganic perovskite having a three-dimensional crystal structure may have an ABX₃ structure. In addition, the organic-inorganic perovskite having a two-dimensional crystal structure may have a structure of ABX₃, A₂BX₄, ABX₄, or Aₙ₋₁PbₙX₃ₙ₊₁ (n is an integer between 2 and 6). In addition, the organic-inorganic perovskite having a one-dimensional crystal structure may have an A₃BX₅ structure. In addition, the organic-inorganic perovskite having a zero-dimensional crystal structure may have an A₄BX₆ structure.

In this case, A is an amidinium group organic material or an organic ammonium material, B is a metal, and X is a halogen.

For example, the amidinium group organic material is formamidinium (NH₂CH═NH⁺), acetamidinium (NH₂C(CH)═NH₂⁺) or guamidinium (NHC(NH)═NH⁺), and the organic ammonium material is (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂ (n is an integer greater than or equal to 1, x is an integer greater than or equal to 1).

In addition, B may be a divalent transition metal, rare earth metal, alkaline earth metal, Pb, Sn, Ge, Ga, In, Al, Sb, Bi, Po, or a combination thereof. The rare earth metal may be Ge, Sn, Pb, Eu, or Yb. Further, the alkaline earth metal may be, for example, Ca or Sr. In addition, X may be Cl, Br, I, or a combination thereof.

On the other hand, the first solution can be prepared by combining AX and BX₂ in a certain ratio. That is, the first solution may be formed by dissolving AX and BX₂ in a polar solvent at a predetermined ratio. For example, by dissolving AX and BX₂ in a polar solvent in a ratio of 2:1, a first solution in which A₂BX₃ organic-inorganic perovskite is dissolved may be prepared.

In addition, the non-polar solvent may include dichloroethylene, trichloroethylene, chloroform, chlorobenzene, dichlorobenzene, styrene, dimethylformamide, dimethylsulfoxide, xylene, toluene, cyclohexene or isopropyl alcohol, but is not limited thereto.

In addition, surfactants may include alkyl halides or carboxylic acids.

In this case, the alkyl halide may have a structure of alkyl-X. The halogen element corresponding to X may include Cl, Br, or I. In addition, the alkyl structure includes an acyclic alkyl having a structure of CₙH₂ₙ₊₁, a primary alcohol having a structure such as CₙH₂ₙ₊₁OH, a secondary alcohol, a tertiary alcohol, alkylamine having a structure of alkyl-N(ex. Hexadecyl amine, 9-Octadecenylamine 1-Amino-9-octadecene (C₁₉H₃₇N)), p-substituted aniline, phenyl ammonium (phenyl ammonium) or fluorine ammonium.

In addition, carboxylic acid is 4,4′-azobis (4-cyanopaleric acid) (4,4′-azobis (4-cyanovaleric acid)), acetic acid, 5-aminosalicylic acid, acrylic acid, L-aspentic acid, 6-bromohexanoic acid, bromoacetic acid, dichloro acetic acid, ethylenediaminetetraacetic acid, isobutyric acid, itaconic acid, maleic acid, r-maleimidobutyric acid, L-malic acid, 4-nitrobenzoic acid, 1-pyrenecarboxylic acid or oleic acid, but is not limited to thereto.

Next, the first solution is mixed with the second solution to form perovskite nanocrystal particles.

In the step of forming perovskite nanocrystal particles by mixing the first solution with the second solution, it is preferable to mix the first solution dropwise with the second solution. In addition, when the first solution is mixed with the second solution, the second solution may be stirred. For example, when first solution in which organic-inorganic perovskite (OIP) is dissolved is slowly added dropwise to the second solution in which an alkyl halide surfactant is dissolved while being strongly stirred, nanocrystal particles may be synthesized.

When the first solution is dropped into the second solution and mixed, organic-inorganic perovskite (OIP) is precipitated from the second solution due to a solubility difference. The organic-inorganic perovskite (OIP) precipitated in the second solution is stabilized by an alkyl halide surfactant to generate well-dispersed organic-inorganic perovskite nanocrystals (OIP-NC). Accordingly, it is possible to prepare organic-inorganic hybrid perovskite nanocrystal particles including organic-inorganic perovskite nanocrystals and a plurality of alkyl halide organic ligands surrounding the organic-inorganic perovskite nanocrystals.

Meanwhile, the size of the organic-inorganic perovskite nanocrystal particles can be controlled by the length of the alkyl halide surfactant or shape factor/amount of the alkyl halide surfactant. For example, the shape factor such that is a linear, tapered, or inverted triangular surfactant may influence the size of the perovskite nanocrystal particle.

In addition, the organic-inorganic hybrid perovskite nanocrystal particles according to an embodiment of the present inventive concept may have a core-shell structure.

Hereinafter, organic-inorganic hybrid perovskite nanocrystal particle having core-shell structure according to an embodiment of the present inventive concept will be described.

FIG. 6 is a schematic diagram and an energy band diagram of an organic-inorganic perovskite nanocrystal particle having core-shell structure according to an embodiment of the present inventive concept.

Referring to FIG. 6 (a), For convenience of description, organic ligands that may be bound to the surface of the core or shell are omitted. The core-shell structure of the organic-inorganic perovskite nanocrystal particles 100′ according to the present inventive concept has a core 115 and a shell 130 surrounding the core 115. Material having a band gap larger than that of the core 115 may be used as the material of the shell 130.

Referring to FIG. 6(b), the energy band gap of the shell 130 is larger than the energy band gap of the core 115, so that excitons are more confined to the core perovskite.

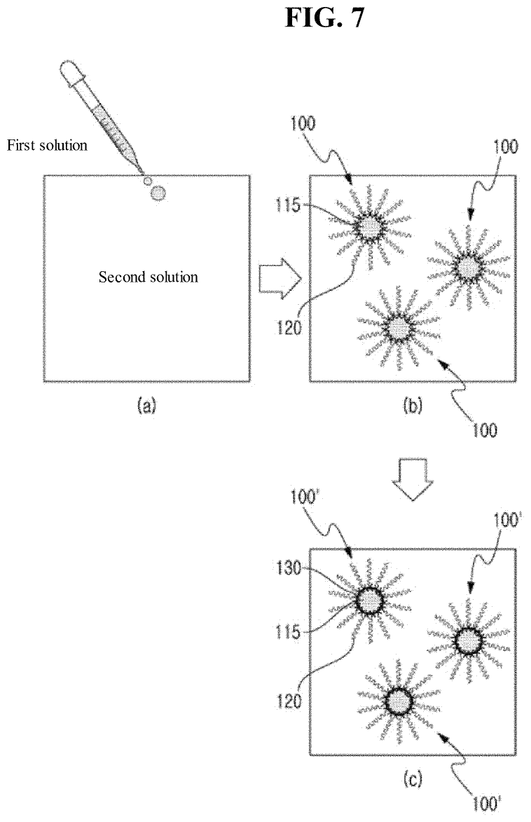

FIG. 7 is a schematic diagram showing a method of manufacturing organic-inorganic perovskite nanocrystal particle having core-shell structure according to an embodiment of the present inventive concept.

The method for producing an organic-inorganic perovskite nanocrystal particle of a core-shell structure according to an embodiment of the present inventive concept comprises step of preparing a first solution in which organic-inorganic perovskite is dissolved in a polar solvent and preparing a second solution in which an alkyl halide surfactant is dissolved in a nonpolar solution. Furthermore, the method comprises step of forming a core including a first organic-inorganic perovskite nanocrystal by mixing the first solution with the second solution, and forming a shell that surrounds the core and is consisted of a material having a larger band gap than the core.

Referring to FIG. 7(a), a first solution in which an organic-inorganic perovskite is dissolved in a polar solvent is added dropwise to a second solution in which an alkyl halide surfactant is dissolved in a non-polar solvent.

Referring to FIG. 7(b), when the first solution is added to the second solution, the organic-inorganic perovskite is precipitated in the second solution due to the solubility difference, the precipitated organic-inorganic perovskite is surrounded by alkyl halide surfactants and the surface of precipitated organic-inorganic perovskite may be stabilized and stabilized by alkyl halide surfactants. Therefore, well-dispersed organic-inorganic perovskite nanocrystal particles 100 including organic-inorganic perovskite nanocrystal core 115 may be manufactured. The perovskite nanocrystal core 115 may be surrounded by the alkyl halide organic ligands 120.

Furthermore, detailed description of FIG. 7(a) and FIG. 7(b) is the same content as described in FIG. 5 and thus will be omitted.

Referring to FIG. 7(c), a shell 130 is formed that surrounds the core 115 and includes a material having a larger band gap than the core 115 to form a core-shell structure of organic-inorganic perovskite 100′.

For the methods of forming such a shell, the following five methods can be used.

As a first method, a shell may be formed using a second organic-inorganic perovskite solution or an inorganic semiconductor solution. That is, a third solution in which an inorganic semiconductor or a second organic-inorganic perovskite having a larger bandgap than the first organic-inorganic perovskite is dissolved is added to the second solution, so that a shell surrounding the core and including a second organic-inorganic perovskite, inorganic semiconductor or organic polymers may be formed.

For example, in a state in which the organic-inorganic hybrid perovskite (MAPbBr₃) solution produced through the above-described method (inverse nano-emulsion method) is strongly stirred, an organic-inorganic perovskite (MAPbCl₃) solution having a larger band gap than MAPbBr₃, or inorganic semiconductor solution such as ZnS or metal oxide, or an organic polymer such as polyethylene glycol, polyethylene oxide, polyvinylpyrrolidone, polyethyleneimine or polyvinyl alcohol (PVA) may be slowly dropped dropwise to form a shell including the second organic-inorganic perovskite nanocrystals (MAPbCl₃) or an inorganic semiconductor. MA in this case means methyl ammonium.

This is because core perovskite and shell perovskite may be mixed with each other to form an alloy or adhere to each other, so that the organic-inorganic perovskite nanocrystals of the core-shell structure can be synthesized. Therefore, it is possible to form organic-inorganic perovskite nanocrystal particles having a MAPbBr₃/MAPbCl₃ core-shell structure. As a second method, a shell can be formed using an organic ammonium halide solution.

That is, a large amount of the organic ammonium halide solution is added to the second solution and then stirred to form a shell surrounding the core and having a larger band gap than the core.

For example, the MACl solution is added to the organic-inorganic perovskite (MAPbBr₃) solution produced through the above method (Inverse nano-emulsion method), and stirred vigorously. Due to excess MACl, MAPbBr₃ of surface is changed to MAPbBr₃,Clₓ, and shell having MAPbBr₃—Clₓ may be formed. Accordingly, it is possible to form organic-inorganic perovskite nanocrystal particles having a MAPbBr₃/MAPbBr₃₋ₓClₓ core-shell structure.

As a third method, the shell can be formed using a pyrolysis/synthesis method. That is, after thermally decomposing the surface of the core by heat-treating the second solution, an organic ammonium halide solution is added to the heat-treated second solution to synthesize the surface again, so that shell surrounding the core and having larger band gap than that of the core may be formed.

For example, after heat-treating the organic-inorganic perovskite (MAPbBr₃) solution produced through the inverse nano-emulsion method as described above, thermally decomposing the surface to change to PbBr₂, and then adding the MACl solution. Thus, the shell can be formed by synthesizing the surface of MAPbBr₂Cl again.

Accordingly, MAPbBr₃/MAPbBr₂Cl core-shell structure organic-inorganic perovskite nanocrystal particles can be formed.

Therefore, the organic-inorganic hybrid perovskite nanocrystal particles of the core-shell structure formed according to the present inventive concept form a shell with a material having a larger band gap than the core, so that excitons are better confined to the core. It is possible to improve the durability of nanocrystals by using stable perovskite in the air or inorganic semiconductor to prevent core perovskite from being exposed to air. As a fourth method, a shell can be formed using an organic semiconductor solution.

That is, an organic semiconductor having a larger band gap than the organic-inorganic perovskite is previously dissolved in the second solution, and the first solution in which the above-described first organic-inorganic perovskite is dissolved is added to this second solution. Thus, a core including the first organic-inorganic perovskite nanocrystal and a shell including an organic semiconductor material surrounding the core may be formed.

This allows organic-inorganic perovskite with a core-shell structure to be synthesized because the organic semiconductor adheres to the surface of the core perovskite. Accordingly, it is possible to form light emitter of an organic-inorganic perovskite nanocrystal particle having core-shell structure of a MAPbBr₃-organic semiconductor.

As a fifth method, a shell can be formed using a selective extraction method. That is, by adding a small amount of IPA solvent to the second solution in which the core including the first organic-inorganic perovskite nanocrystal is formed, MABr is selectively extracted from the surface of the nanocrystal, and the surface is formed only with PbBr₂ to surround the core, and is formed as a shell having a larger band gap than the core.

For example, by adding a small amount of IPA to the organic-inorganic perovskite (MAPbBr₃) solution produced through the above method (Inverse nano-emulsion method), only MABr on the nanocrystal surface is selectively dissolved on the surface. PbBr₂ shell can be formed by extracting so that only PbBr₂ remains. That is, MABr on the surface of MAPbBr₃ may be removed through selective extraction. Therefore, it is possible to form a light emitter of organic-inorganic perovskite nanocrystal particle having MAPbBr₃—PbBr₂ core-shell structure.

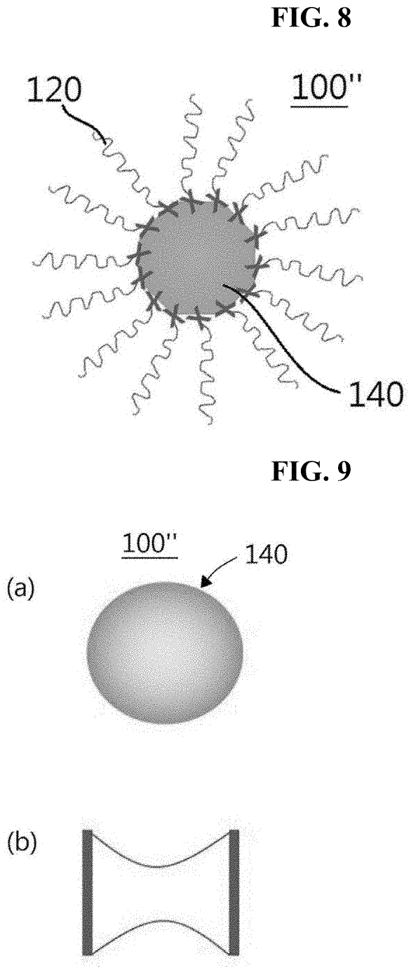

FIG. 8 is a schematic diagram showing an organic-inorganic perovskite nanocrystal particle having a gradient composition structure according to an embodiment of the present inventive concept.

Referring to FIG. 8, an organic-inorganic perovskite nanocrystal particle 100″ having a structure having a gradient composition according to an embodiment of the present inventive concept has an organic-inorganic perovskite capable of being dispersed in an organic solvent, and the organic-inorganic perovskite 140) has a gradient composition structure whose composition changes from the center toward the outside, and the organic solvent may be a polar solvent or a non-polar solvent.

The organic-inorganic perovskite 140 has a structure of ABX₃₋ₘX′ₘ, A₂BX₄₋ₗX′ₗ or ABX₄₋ₖX′ₖ, wherein A is an amidinium group organic material or an organic ammonium, and B is a metal, X is Br, and X′ may be Cl. In addition, the m, l, and k values are characterized by increasing from the center of the organic-inorganic perovskite 140 toward the outside.

Accordingly, the energy band gap increases from the center of the organic-inorganic perovskite 140 toward the outside.

For example, the amidinium group organic material is formamidinium (NH₂CH═NH⁺), acetamidinium (NH₂C(CH)═NH₂⁺) or guamidinium (NHC(NH)═NH⁺), and the organic ammonium is (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂ (n is an integer of 1 or more, x is an integer of 1 or more).

B may be a divalent transition metal, rare earth metal, alkaline earth metal, Pb, Sn, Ge, Ga, In, Al, Sb, Bi, Po, or a combination thereof.

Meanwhile, the m, l, and k values may gradually increase from the center of the nanocrystalline structure toward the outside. Therefore, the energy band gap may gradually increase according to the composition change.

As another example, the m, l, and k values may increase step by step from the center of the nanocrystal toward the outside. Therefore, according to the composition change, the energy band gap may increase in the form of a step.

In addition, a plurality of organic ligands 120 surrounding the organic-inorganic perovskite 140 may be further included. The organic ligand 120 may include an alkyl halide.

This alkyl halide may be an alkyl-X structure. The halogen element corresponding to X may include Cl, Br, or I. In addition, the alkyl structure includes an acyclic alkyl having a structure of CₙH₂ₙ₊₁, a primary alcohol having a structure such as CₙH₂ₙ₊₁OH, a secondary alcohol, a tertiary alcohol, alkylamine having a structure of alkyl-N(e.g. hexadecyl amine, 9-octadecenylamine 1-amino-9-octadecene (C₁₉H₃₇N)), p-substituted aniline, phenyl ammonium (phenyl ammonium) or fluorine ammonium.

Therefore, by making the nanocrystal structure into a gradient-alloy type, the content of perovskite present outside the nanocrystal structure and perovskite composition can be gradually changed. The gradual content change in the nanocrystal structure uniformly controls the fraction in the nanocrystal structure, reduces surface oxidation, and improves exciton confinement in the perovskite present in a large amount inside, thereby increasing luminescence efficiency. In addition, durability-stability can also be increased.

A method of manufacturing an organic-inorganic perovskite nanocrystal particle having a gradient composition according to an embodiment of the present inventive concept will be described.

The method for preparing organic-inorganic perovskite nanocrystal particles having a gradient composition according to an embodiment of the present inventive concept includes step of preparing the organic-inorganic perovskite nanocrystal particles having a core-shell structure, and step of forming gradient composition through heat-treating the organic-inorganic perovskite nanocrystal particles having core-shell structure to induce mutual diffusion.

First, organic-inorganic perovskite nanocrystal particles having a core-shell structure are prepared. A method for manufacturing the organic-inorganic perovskite nanocrystal particles having a related core-shell structure is the same as described above with reference to FIG. 7, and a detailed description thereof will be omitted.

Then, the organic-inorganic perovskite nanocrystal particles having the core-shell structure may be heat-treated to form a gradient composition through mutual diffusion.

For example, an organic-inorganic perovskite having a core-shell structure is annealed at a high temperature to form a solid solution, and then heat-treated to obtain a gradient composition through interdiffusion.

For example, the heat treatment temperature may be 100° C. to 150° C. Interdiffusion can be induced by annealing at this heat treatment temperature.

According to another embodiment of the present inventive concept, a method for manufacturing an organic-inorganic perovskite nanocrystal particle having a gradient composition includes forming a first organic-inorganic perovskite nanocrystal core and forming a second organic-inorganic perovskite nanocrystal shell having a gradient composition surrounding the core.

First, a first organic-inorganic perovskite nanocrystal core is formed. This is the same as the method of forming the perovskite nanocrystal described above, so a detailed description thereof will be omitted.

Then, a second organic-inorganic perovskite nanocrystal shell having a gradient composition surrounding the core is formed.

The second organic-inorganic perovskite has a structure of ABX₃₋ₘX′ₘ, A₂BX₄₋ₗX′ₗ or ABX₄₋ₖX′ₖ, wherein A is an amidinium group organic material or an organic ammonium, B is a metal, X is Br, and X′ may be Cl.

Accordingly, a third solution in which the second organic-inorganic perovskite is dissolved may be added to the second solution while increasing the m, l or k value.

That is, the solution in which the composition of ABX₃₋ₘX′ₘ, A₂BX₄₋ₗX′ₗ, or ABX₄₋ₖX′ₖ is controlled is continuously dropped to form a shell whose composition is continuously changed.

FIG. 9 is a schematic diagram showing an organic-inorganic perovskite nanocrystal particle having a gradient composition and an energy band diagram thereof according to an embodiment of the present inventive concept.

Referring to FIG. 9(a), it can be seen that the nanocrystal particles 100 according to the present inventive concept have an organic-inorganic perovskite 140 having nanocrystal structure having a varying gradient composition. Referring to FIG. 9(b), by changing the composition of the material from the center of the organic-inorganic perovskite 140 having nanocrystal structure toward the outside, the energy band gap may be increased from the center toward the outside.

Meanwhile, the perovskite nanocrystal particles according to the present inventive concept may be doped perovskite nanocrystal particles.

The doped perovskite includes a structure of ABX₃, A₂BX₄, ABX₄ or Aₙ₋₁BₙX₃ₙ₊₁ (n is an integer between 2 and 6), and a part of A is substituted with A′, or a part of B is B′, or a part of X is substituted with X′, wherein A and A′ are an amidinium group organic material, an organic ammonium, or an alkali metal, and B and B′ are a metal. And X and X′ may be halogen elements.

The amidinium group organic material is formamidinium (NH₂CH═NH⁺), acetamidinium (NH₂C(CH)═NH₂⁺) or guamidinium (NHC(NH)═NH⁺) ion, and the organic ammonium may be (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂)(n is an integer greater than or equal to 1, x is an integer greater than or equal to 1). B and B′ are divalent transition metals, rare earth metals, alkaline earth metals, Pb, Sn, Ge, Ga, In, Al, Sb, Bi or Po, and X and X′ may be Cl, Br or I.

In addition, a portion of A is substituted with A′, a portion of B is substituted with B′, or a portion of X is substituted with X′ is characterized in range of 0.1% to 5%.

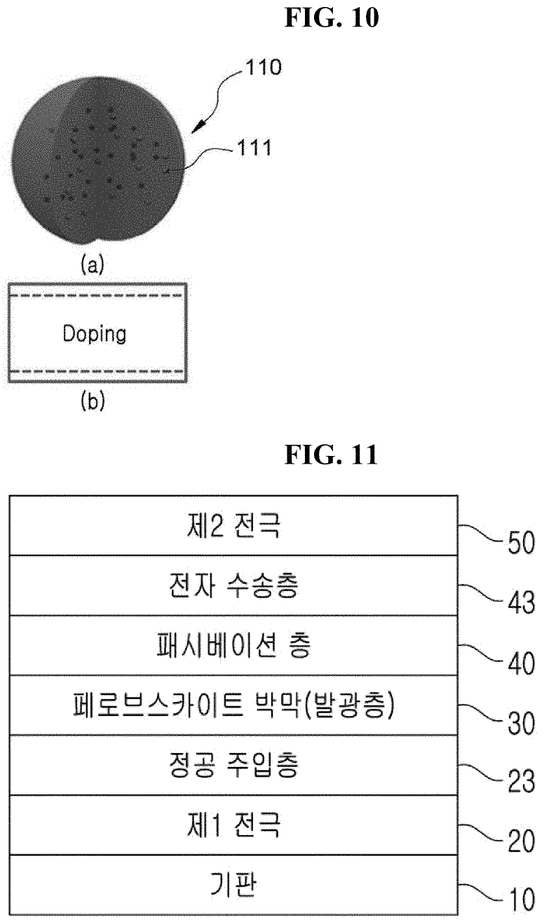

FIG. 10 is a schematic diagram showing a doped perovskite nanocrystal particle and an energy band diagram thereof according to an embodiment of the present inventive concept.

FIG. 10(a) is a partially cut schematic diagram of an organic-inorganic perovskite 110 having nanocrystal structure, the organic-inorganic perovskite 110 is doped with a dopant 111. FIG. 10(b) is a band diagram of the doped organic-inorganic perovskite 110.

Referring to FIGS. 10(a) and 10(b), a semiconductor type may be changed to an n-type or a p-type by doping an organic-inorganic perovskite. For example, when MAPbI₃ organic-inorganic perovskite are partially doped with Cl, the organic-inorganic perovskite is changed to n-type and electro-optical properties can be suitably controlled. MA is methyl ammonium.

A doped organic-inorganic perovskite nanocrystal particle according to an embodiment of the present inventive concept will be described. A method of manufacturing through the inverse nano-emulsion method will be described as an example.

First, a first solution in which a doped organic-inorganic perovskite is dissolved in a polar solvent is added dropwise to a second solution in which an alkyl halide surfactant is dissolved in a non-polar solvent.

The polar solvent may include dimethylformamide, gamma butyrolactone, N-methylpyrrolidone, or dimethylsulfoxide, but is not limited thereto.

The doped organic-inorganic perovskite includes a structure of ABX₃, A₂BX₄, ABX₄ or Aₙ₋₁BₙX₃ₙ₊₁, and a part of A is substituted with A′, or a part of B is substituted with B′, a part of X′ is substituted with X′.

A and A′ may be an amidinium group organic material or an organic ammonium, B and B′ may be metal, and X and X′ may be halogen elements. For example, the amidinium group organic material is formamidinium (NH₂CH═NH⁺), acetamidinium (NH₂C(CH)═NH₂⁺) or guamidinium (NHC(NH)═NH⁺) ion, and the organic ammonium is (CH₃NH₃)—, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂)(n is an integer greater than or equal to 1, x is an integer greater than or equal to 1). B and B′ are divalent transition metals, rare earth metals, alkaline earth metals, Pb, Sn, Ge, Ga, In, Al, Sb, Bi or Po, and X and X′ may be Cl, Br or I.

In addition, A and A′ are different organic substances, B and B′ are different metals, and X and X′ are different halogen elements. Furthermore, doped X′ is preferably selected as an element that does not form an alloy with X.

For example, a first solution may be formed by adding CH₃NH₃I, PbI₂, and PbCl₂ to a DMF solvent. In this case, the molar ratio of CH₃NH₃I:PbI₂ and PbCl₂ may be 1:1, and the molar ratio of PbI₂:PbCl₂ may be set to 97:3.

Meanwhile, as an example of the synthesis of AX, when A is CH₃NH₃ and X is Br, CH₃NH₃Br can be obtained by dissolving CH₃NH₂ (methylamine) and HBr (hydroiodic acid) in a nitrogen atmosphere and by solvent evaporation.

Then, when the first solution is added to the second solution, the doped organic-inorganic perovskite is precipitated from the second solution due to the solubility difference, and the doped organic-inorganic perovskite is surrounded with halide surfactants. So, a well-dispersed doped organic-inorganic perovskite nanocrystal particle 100 is formed while the doped organic-inorganic perovskite is surrounded by a halide surfactant and the surface of the doped organic-inorganic perovskite. The surface of the doped organic-inorganic perovskite is surrounded by organic ligands, which are alkyl halides.

Thereafter, a polar solvent including doped organic-inorganic hybrid perovskite nanocrystal particles dispersed in a non-polar solvent in which an alkyl halide surfactant is dissolved is selectively evaporated by applying heat, or co-solvent in which both polar solvents and non-polar solvents can be dissolved is added. Therefore, polar solvent including nanocrystal particles can be selectively extracted from a non-polar solvent, and doped organic-inorganic perovskite nanocrystal particles can be obtained.

Hereinafter, a method of manufacturing a thin film of metal halide perovskite nanocrystal particles according to an embodiment of the present inventive concept will be described.

The method of manufacturing a thin film of metal halide perovskite nanocrystal particles according to an embodiment of the present inventive concept includes preparing an organic solution containing metal halide perovskite dispersed in an organic solvent, applying the organic solution to form a thin film of perovskite nanocrystal particles and drying the formed the thin film of nanocrystal particles.

First, the organic solution containing metal halide perovskite dispersed in an organic solvent is prepared.

The organic solvent includes a polar solvent or a non-polar solvent, and the polar solvent includes dimethylformamide, gamma butyrolactone, N-methylpyrrolidone, or dimethyl sulfoxide, and the non-polar solvent includes dichloroethylene, trichloroethylene, chloroform, chlorobenzene, dichlorobenzene, styrene, dimethylformamide, dimethyl sulfoxide, xylene, toluene, cyclohexene or isopropyl alcohol.

Since the description of the metal halide perovskite nanocrystal particles is the same as the above description, it will be omitted to avoid redundant description.

Preparing the organic solution includes preparing a first solution in which a metal halide perovskite is dissolved in a polar solvent and a second solution in which a surfactant is dissolved in a non-polar solvent, and the first solution is added to the second solution. Mixing with the metal halide perovskite may include the step of forming nanocrystal particles. As already described above in connection with this, a detailed description will be omitted.

Then, the organic solution is applied on a substrate to form a thin film of perovskite nanocrystal particles. The step of forming the thin film of perovskite nanocrystal particle includes performing bar-coating, spray coating, slot-die coating, gravure coating, and blade coating, screen printing, nozzle printing, inkjet printing, electrohydrodynamic-jet printing, electrospray, or electrospinning.

Therefore, when forming a thin film through such a printing method, the perovskite nanocrystal particles form a thin film in a state of crystallization, so that coating process of the present inventive concept is not affected by coating speed, coating environment and crystallinity of underlying layer compared to a bulk perovskite thin film in which crystallization is formed during coating.

However, when a thin film is manufactured using such a printing method, the evaporation rate of the solvent is slow, so that large crystals (>μm) may be formed through recrystallization through aggregation of nanocrystal particles.

Therefore, the formed thin film of nanocrystal particles is dried. Preferably, it can be dried through air blowing. Accordingly, in the present inventive concept, after the organic solution is coated on a substrate, a drying step is further performed to prevent recrystallization between the nanocrystal particles. That is, the thin film formed using bar coating or the like is directly dried through air spraying, so that recrystallization between nanocrystal particles can be prevented.

Next, a passivation layer 40 is formed on the perovskite thin film 30.

The perovskite thin film 30 exhibits relatively low luminescence efficiency due to surface defects and charge carrier imbalance in the light-emitting device. Accordingly, there is a need for a method capable of eliminating defects in a perovskite thin film and resolving the charge imbalance in a light-emitting device.

Accordingly, the present inventive concept is characterized in that a passivation layer is formed on the perovskite thin film in a light-emitting device including a perovskite thin film as a light-emitting layer.

In the perovskite light-emitting device according to the present inventive concept, the passivation layer may include one or more compounds of Formulas 1 to 4 below.

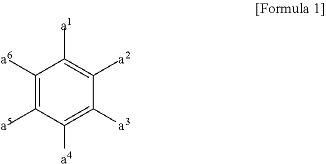

(In Formula 1, a¹ to a⁶ are H, CH₃, or CH₂X, wherein at least three of a¹ to a⁶ are CH₂X, and X is a halogen element)

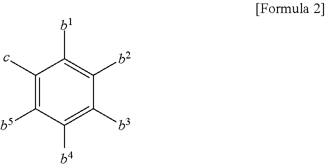

(In Formula 2, b¹ to b⁵ is halogen element, c is

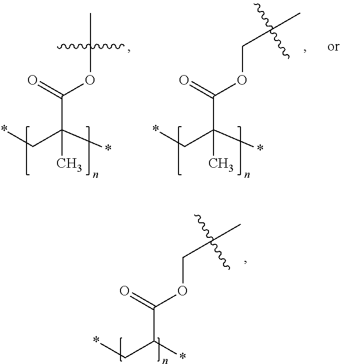

and n is integer 1 to 100)

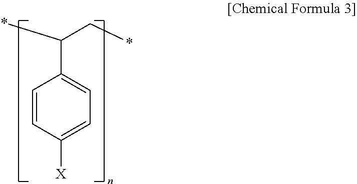

(In Formula 3, X is halogen element, and n is integer 1 to 100)

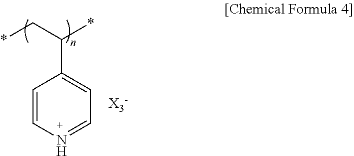

(In Formula 4, X is halogen element, and n is integer 1 to 100)

The compounds of Chemical Formulas 1 to 4 are organic compounds containing halogen, and may stabilize defects in perovskite thin film by supplementing the deficiency of halogen in the perovskite crystal.

Preferably, the compound constituting the passivation layer is selected group consisted of (1,3,5-tris(bromomethyl)benzene), 2,4,6-tris(bromomethyl)mesitylene (TBMM), 1,2,4,5-tetrakis(bromomethyl)benzene, hexakis(bromomethyl)benzene, poly(pentabromophenyl methacrylate), poly(pentabromobenzyl methacrylate), poly(pentabromobenzyl acrylate), poly(4-bromostyrene) and poly(4-vinylpyridinium tribromide), and more preferably 2,4,6-tris(bromomethyl)mesitylene (TBMM) can be used.

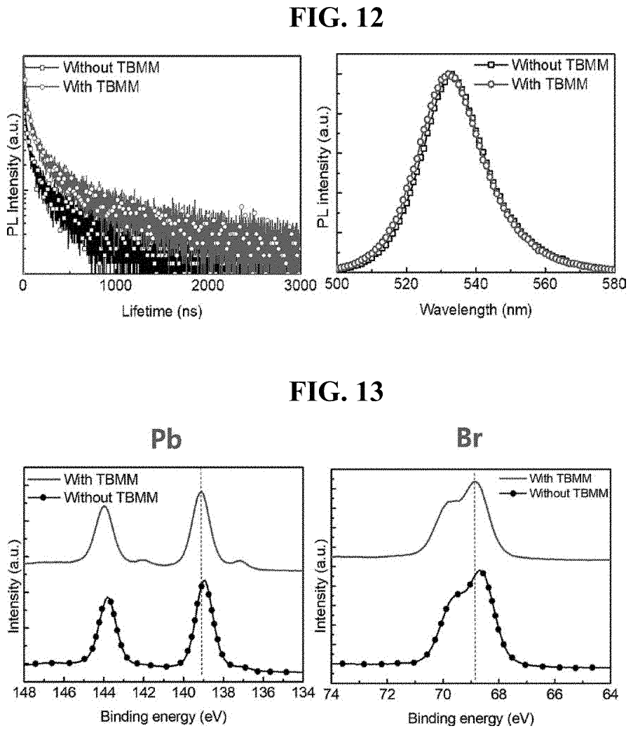

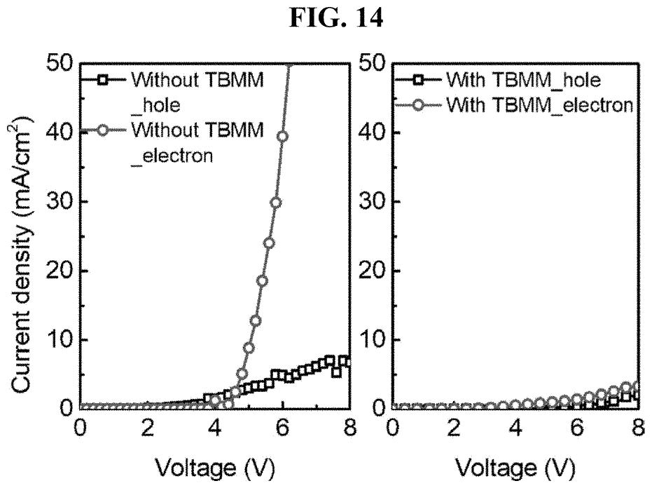

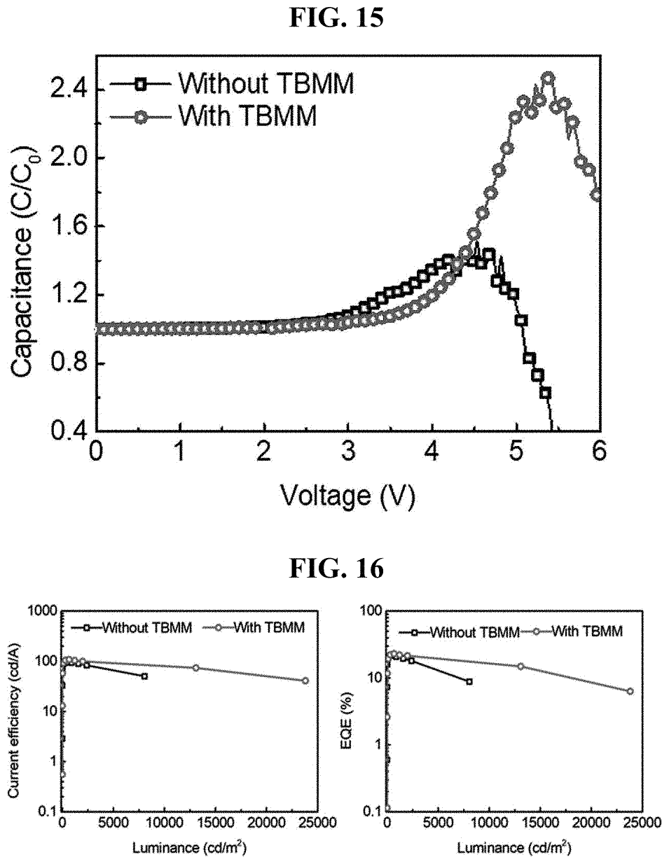

In one embodiment of the present inventive concept, as a result of measuring the photoluminescence properties before and after coating the TBMM of the compounds of Formula 1, on the perovskite thin film of the metal halide perovskite nanocrystal particles, photoluminescence lifetime (PL) is extended (see FIG. 12), the binding energy of the perovskite elements is increased (see FIG. 13), and the current density of holes and electrons becomes similar, thereby solving the charge imbalance in the device (FIG. 14), it is confirmed that the electric capacity was increased (see FIG. 15), and the luminescence efficiency and maximum luminance are improved (see FIG. 16).

Therefore, the compound according to the present inventive concept can be usefully used as a passivation layer on a perovskite thin film.

It is preferable that the thickness of the passivation layer 40 is 1-100 nm, and if the thickness of the passivation layer 40 exceeds 100 nm, there is a problem that charge injection decreases due to its insulating property.

The passivation layer 40 may be formed by performing spin coating, bar coating, spray coating, slot die coating, gravure coating, blade coating, screen printing, nozzle printing, inkjet printing, electrohydrodynamic jet printing, electrospray or electrospinning.

A second electrode 50 may be formed on the passivation layer 40.

The second electrode 50 is a cathode into which electrons are injected, and may be made of a material having a conductive property. When the second electrode 50 is a negative electrode, it is preferably a metal, and for example, a metal such as aluminum, magnesium, calcium, sodium, potassium, indium, yttrium, lithium, silver, lead, cesium, or a combination thereof.

Meanwhile, in one embodiment of the present inventive concept, the first electrode 20 may be used as a cathode and the second electrode 50 may be used as an anode.

The first electrode 20 or the second electrode 50 can be formed with physical vapor deposition (PVD), chemical vapor deposition (CVD), sputtering, pulsed laser deposition (PLD), evaporation method, electron beam evaporation method, atomic layer deposition (ALD) or molecular beam epitaxy deposition (MBE).

On the other hand, in the light-emitting device according to the embodiment of the present inventive concept, when the first electrode 20 is an anode and the second electrode 50 is a cathode, as shown in FIG. 11, hole injection layer 23 for facilitating injection of holes and a hole transport layer for transporting holes may be provided between the perovskite thin film (light-emitting layer) 30 and the first electrode 20. In addition, an electron transport layer 43 for transporting electrons and an electron injection layer for facilitating injection of electrons may be provided between the passivation layer 40 and the second electrode 50.

In addition, a hole blocking layer (not shown) may be disposed between the perovskite thin film (light-emitting layer) 30 and the electron transport layer 43. In addition, an electron blocking layer (not shown) may be disposed between the perovskite thin film (light-emitting layer) 30 and the hole transport layer. However, the present inventive concept is not limited thereto, and the electron transport layer 43 may function as a hole blocking layer, or the hole transport layer may function as an electron blocking layer.

The hole injection layer 23 and/or the hole transport layer are layers having a HOMO level between the work function level of the first electrode (anode) 20 and the HOMO level of the perovskite thin film (light-emitting layer) 30, and their function is to increase the injection or transport efficiency of holes from the electrode (anode) 20 to the perovskite thin film (light-emitting layer) 30.

The hole injection layer or the hole transport layer may include a material commonly used as a hole transport material, and one layer may include different hole transport material. Hole transport materials include, for example, mCP (N,Ndicarbazolyl-3,5-benzene), PEDOT:PSS (poly(3,4-ethylenedioxythiophene):polystyrenesulfonate), NPD (N,N′-di(1-naphthyl)-N,N′-diphenylbenzidine), N,N′-diphenyl-N,N′-di(3-methylphenyl)-4,4′-diaminobiphenyl (TPD), DNTPD (N4,N4′-Bis[4-[bis(3-methylphenyl)amino]phenyl]-N4,N4′-diphenyl-[1,1′-biphenyl]-4,4′-diamine), N,N′-diphenyl-N,N′-dinaphthyl-4,4′-diaminobiphenyl, N,N,N′N′-tetra-p-tolyl-4,4′-diaminobiphenyl, N,N,N′N′-tetraphenyl-4,4′-diaminobiphenyl, Porphyrin compound derivatives such as copper(II)1,10,15,20-tetraphenyl-21H,23H-porphyrin, TAPC (1,1-Bis[4-[N,N′-Di(p-tolyl)Amino]Phenyl]Cyclohexane), triarylamine derivatives such as N,N,N-tri(p-tolyl)amine, 4,4′,4′-tris[N-(3-methylphenyl)-N-phenylamino]triphenylamine, carbazole derivatives such as N-phenylcarbazole and polyvinylcarbazole, phthalocyanine derivatives such as metal-free phthalocyanine and copper phthalocyanine, starburst amine derivatives, enaminestilbene derivatives, derivatives of aromatic tertiary amines and styryl amine compounds or polysilane. Such a hole transport material may serve as an electron blocking layer.

The hole blocking layer serves to prevent diffusion of triplet excitons or holes in the direction of the second electrode (cathode) and may be arbitrarily selected from known hole blocking materials. For example, oxadiazole derivatives, triazole derivatives, phenanthroline derivatives, or TSPO1 (diphenylphosphine oxide-4-(triphenylsilyl)phenyl) can be used.

The electron injection layer and/or the electron transport layer are layers having an LUMO level between the work function level of the second electrode (cathode) and the LUMO level of the perovskite thin film (light-emitting layer) 30, and the second electrode (cathode) 50 functions to increase the injection or transport efficiency of electrons into the perovskite thin film (light-emitting layer) 30.

The electron injection layer may be, for example, LiF, NaCl, CsF, Li₂O, BaO, BaF₂, or Liq (lithium quinolate).

The electron transport layer includes TSPO1 (diphenylphosphine oxide-4-(triphenylsilyl)phenyl), TPBi (1,3,5-tris(N-phenylbenzimidazol-2-yl)benzene), tris(8-quinolinolate)aluminum (Alq3), 2,5-diaryl silol derivative (PyPySPyPy), perfluorinated compound (PF-6P), COTs (Octasubstituted cyclooctatetraene), TAZ (see formula below), Bphen (4,7-diphenyl-1, It may be 10-phenanthroline (4,7-diphenyl-1,10-phenanthroline)), BCP (see formula below), or BAlq (see formula below).

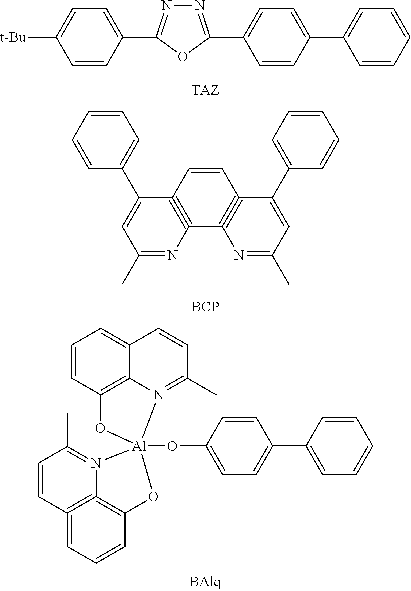

In addition, the present inventive concept provides a method of manufacturing a perovskite light-emitting device including a passivation layer.

A method of manufacturing a perovskite light-emitting device according to the present inventive concept comprises forming a first electrode on a substrate, forming a perovskite thin film on the first electrode, forming a passivation layer including at least one compound of Formulas 1 to 4 on the perovskite thin film, and forming a second electrode on the passivation layer.

Hereinafter, a method of manufacturing a perovskite light-emitting device including a passivation layer according to an embodiment of the present inventive concept will be described with reference to the structure of FIG. 1.

First, the substrate 10 is prepared.

Next, a first electrode 20 may be formed on the substrate 10. This first electrode may be formed using a vapor deposition method or a sputtering method.

Next, a perovskite thin film 30 may be formed on the first electrode 20. The perovskite has a structure of ABX₃, A₂BX₄, A₃BX₅, A₄BX₆, ABX₄ or Aₙ₋₁PbₙX₃ₙ₊₁ (n is an integer between 2 and 6), wherein A is an organic ammonium ion, an organic amidinium ion, an organic phosphonium ion, an alkali metal ion, or a derivative thereof, wherein B includes a transition metal, a rare earth metal, an alkaline earth metal, an organic material, an inorganic material, ammonium, a derivative thereof, or a combination thereof, wherein X is a halogen ions or combinations of different halogen ions.

The perovskite thin film 30 may be a bulk polycrystalline thin film or a thin film made of nanocrystal particles, and the nanocrystal particles may have a core-shell structure or a structure having a gradient composition.

Such perovskite thin film 30 can be formed by bar-coating, spray coating, slot-die coating, gravure coating, blade-coating, screen printing, nozzle printing, inkjet printing, electrohydrodynamic-jet printing, electrospray, or electrospinning.

Next, a passivation layer 40 may be formed on the perovskite thin film 30. The passivation layer preferably includes at least one compound of Formulas 1 to 4, and specifically, the compound constituting the passivation layer is (1,3,5-tris(bromomethyl)benzene), 2,4,6-tris(bromomethyl)mesitylene (TBMM), 1,2,4,5-tetrakis(bromomethyl)benzene, hexakis(bromomethyl)benzene, poly(pentabromophenyl methacrylate), poly(pentabromobenzyl methacrylate), poly(pentabromobenzyl acrylate), poly(4-bromostyrene) or poly(4-vinylpyridinium tribromide).

It is preferable that the thickness of the passivation layer 40 is 1-100 nm, and if the thickness of the passivation layer exceeds 100 nm, there is a problem that charge injection decreases due to insulating properties.

The passivation layer 40 can be formed using spin coating, bar coating, spray coating, slot die coating, gravure coating, blade coating, screen printing, nozzle printing, inkjet printing, electrohydrodynamic jet printing, electrospray or electrospinning.

A second electrode 50 may be formed on the passivation layer 40. These two electrodes 20, 50 may be formed using a vapor deposition method or a sputtering method.

In addition, in an embodiment of the present inventive concept, a method of manufacturing the perovskite light-emitting device includes forming a first electrode on a substrate, forming a hole injection layer on the first electrode, forming a perovskite thin film as a light-emitting layer on the hole injection layer, forming a passivation layer including at least one compound of Formulas 1 to 4 on the perovskite thin film, forming an electron transport layer on the passivation layer, and forming a second electrode on the electron transport layer.

Such a hole injection layer or an electron transport layer may be formed by performing a spin coating method, a dip coating method, a thermal evaporation method, or a spray evaporation method.

In the perovskite light-emitting device manufactured as described above, a passivation layer composed of one or more compounds of Formulas 1 to 4 is formed on the perovskite thin film to remove defects of perovskite nanocrystal particles and solve the charge imbalance in the devices, so the maximum efficiency and maximum luminance of a light-emitting device including the perovskite thin film are improved.

### EXAMPLES

Hereinafter, a preferred manufacturing example and an experimental example are presented to aid in the understanding of the present inventive concept. However, the following preparation examples and experimental examples are only intended to aid understanding of the present inventive concept, and the present inventive concept is not limited by the following preparation examples and experimental examples.

### <Preparation Example 1> Preparation of Organic-Inorganic Perovskite Nanocrystal Particles

Organic-inorganic perovskite nanocrystal particles having a three-dimensional structure are formed through the inverse nano-emulsion method.

Specifically, a first solution was prepared by dissolving an organic-inorganic perovskite in a polar solvent. Dimethylformamide is used as a polar solvent, and CH₃NH₃PbBr₃ is used as an organic-inorganic hybrid perovskite. The CH₃NH₃PbBr₃ used is a mixture of CH₃NH₃Br and PbBr₂ in a 1:1 ratio.

Then, a second solution in which an alkyl halide surfactant is dissolved in a non-polar solvent is prepared. Toluene is used as the non-polar solvent, and octadecylammonium bromide (CH₃(CH₂)₁₇NH₃Br) is used as the alkyl halide surfactant.

Then, the first solution is slowly added dropwise to the second solution being strongly stirred to form organic-inorganic perovskite nanocrystal particles having a three-dimensional structure.

Then, the organic-inorganic perovskite nanocrystal particles in a solution state are spin-coated on a glass substrate to form an organic-inorganic perovskite nanocrystal particle thin film (OIP-NP film).

The size of the organic-inorganic perovskite nanocrystal particles formed at this time is about 10 nm.

### <Preparation Example 2> Preparation of Organic-Inorganic Perovskite Nanocrystal Particles Having a Core-Shell Structure

The organic-inorganic perovskite nanocrystal according to Preparation Example 1 is used as a core. In addition, a second organic-inorganic perovskite (MAPbCl₃) solution having a large band gap is slowly dropped drop by drop into the solution containing the organic-inorganic perovskite core to form a second organic-inorganic perovskite. An organic-inorganic perovskite nanocrystal particle having a three-dimensional core-shell structure according to an embodiment of the present inventive concept is formed by forming a shell including nanocrystals (MAPbCl₃).

### <Preparation Example 3> Preparation of Organic-Inorganic Perovskite Nanocrystal Particles Having a Gradient Core-Shell Structure

It is carried out in the same manner as in Preparation Example 2, but (CH₃NH₃)₂PbBr₄ is used as a core organic-inorganic perovskite. The (CH₃NH₃)₂PbBr₄ used is a mixture of CH₃NH₃Br and PbBr₂ in a ratio of 2:1.

The formed core-shell type organic-inorganic perovskite nanocrystal particles emit ultraviolet or blue light. The emission spectrum is located at about 520 nm.

### <Preparation Example 4> Preparation of Doped Organic-Inorganic Perovskite Nanocrystal Particles

Doped organic-inorganic perovskite nanocrystal particles according to an embodiment of the present inventive concept are formed. It is formed through the inverse nano-emulsion method.

Specifically, a first solution is prepared by dissolving doped organic-inorganic perovskite in a polar solvent. Dimethylformamide is used as a polar solvent, and CH₃NH₃PbI₃ doped with Cl as an organic-inorganic perovskite is used. The Cl-doped CH₃NH₃PbI₃ used is a mixture of CH₃NH₃I:PbI₂ and PbCl₂ in a 1:1 ratio. In addition, PbBr₂:PbCl₂ is mixed in a 97:3 ratio. Therefore, a first solution in which 3% Cl-doped CH₃NH₃PbI₃ is dissolved is prepared.

Then, a second solution in which an alkyl halide surfactant is dissolved in a non-polar solvent is prepared. Toluene is used as the non-polar solvent, and CH₃(CH₂)₁₇NH₃I is used as the alkyl halide surfactant.

Then, the first solution is slowly added dropwise to the second solution being strongly stirred to form nanocrystal particles including a Cl-doped organic-inorganic perovskite nanocrystal.

Then, the organic-inorganic perovskite nanocrystal particles in a solution state are spin-coated on a glass substrate to form an organic-inorganic perovskite nanocrystal particle thin film (OIP-NP film).

### <Preparation Example 5> Preparation of a Perovskite Light-Emitting Device Including a Passivation Layer

First, after preparing an ITO substrate (a glass substrate coated with an ITO anode), a conductive material PEDOT:PSS (AI4083 from Heraeus) is spin-coated on the ITO anode, and then heat-treated at 150° C. for 30 minutes, such that hole injection layer of 40 nm thickness is formed.

Perovskite thin film for emission layer having organic-inorganic perovskite nanocrystal particle is formed by bar coating. In bar coating, a coating solution in which the organic-inorganic perovskite nanocrystal particles according to Preparation Example 1 are dissolved is coated on the hole injection layer and heat treatment at 90° C. for 10 minutes is performed.

Next, a solution in which 2,4,6-tris(bromomethyl)mesitylene (TBMM) of the following formula is dissolved is coated at 90° C. on the perovskite thin film of organic-inorganic perovskite nanocrystal particles. Heat treatment is performed for 10 minutes to form a passivation layer.

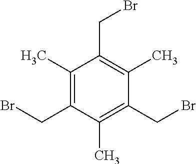

Thereafter, 1,3,5-tris(1-phenyl-1H-benzimidazol-2-yl)benzene (TPBI) having a thickness of 50 nm is deposited on the TBMM passivation layer in a high vacuum of 1×10⁻⁷ Torr or less. Thus, an electron transport layer is formed, an electron injection layer is formed by depositing 1 nm-thick LiF thereon, and 100 nm-thick aluminum is deposited thereon to form a negative electrode, thereby fabricating an organic-inorganic perovskite light-emitting device.

### <Preparation Example 6> Preparation of a Perovskite Light-Emitting Device Including a Passivation Layer

An organic-inorganic perovskite light-emitting device is manufactured in the same manner as in Preparation Example 5 using a solution in which 1,3,5-tris(bromomethyl)benzene of the following formula is dissolved as a material forming the passivation layer.

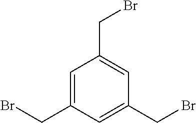 [SMILES: BrCc1cc(CBr)cc(CBr)c1]

### <Preparation Example 7> Preparation of a Perovskite Light-Emitting Device Including a Passivation Layer

An organic/inorganic hybrid perovskite light-emitting device is fabricated in the same manner as in Preparation Example 5 using a solution in which 1,2,4,5-tetrakis(bromomethyl)benzene of the following formula is dissolved as a material forming the passivation layer.

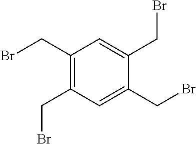 [SMILES: BrCc1cc(CBr)c(CBr)cc1CBr]

### <Preparation Example 8> Preparation of a Perovskite Light-Emitting Device Including a Passivation Layer

An organic/inorganic hybrid perovskite light-emitting device is manufactured in the same manner as in Preparation Example 5 using a solution in which hexakis(bromomethyl)benzene of the following formula is dissolved as a material constituting the passivation layer.

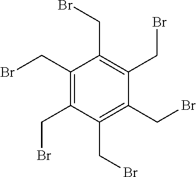 [SMILES: BrCc1c(CBr)c(CBr)c(CBr)c(CBr)c1CBr]

### <Preparation Example 9> Preparation of a Perovskite Light-Emitting Device Including a Passivation Layer

An organic-inorganic perovskite light-emitting device is manufactured in the same manner as in Preparation Example 5 using a solution in which a poly(pentabromophenyl methacrylate) polymer of the following formula is dissolved as a material forming the passivation layer.

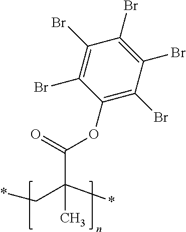

### <Preparation Example 10> Preparation of a Perovskite Light-Emitting Device Including a Passivation Layer

An organic-inorganic perovskite light-emitting device is manufactured in the same manner as in Preparation Example 5 using a solution in which a poly(pentabromobenzyl methacrylate) polymer of the following formula is dissolved as a material forming the passivation layer.

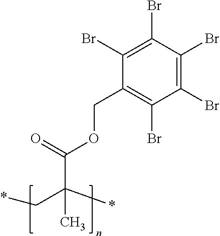

### <Preparation Example 11> Preparation of a Perovskite Light-Emitting Device Including a Passivation Layer

An organic-inorganic perovskite light-emitting device is manufactured in the same manner as in Preparation Example 5 using a solution in which a poly(pentabromobenzyl acrylate) polymer of the following formula is dissolved as a material forming the passivation layer.

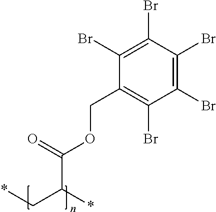

### <Preparation Example 12> Preparation of a Perovskite Light-Emitting Device Including a Passivation Layer

An organic-inorganic perovskite light-emitting device is manufactured in the same manner as in Preparation Example 5 using a solution in which a poly(4-bromostyrene) polymer of the following formula is dissolved as a material forming the passivation layer.

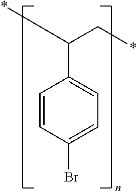

### <Preparation Example 13> Preparation of a Perovskite Light-Emitting Device Including a Passivation Layer

An organic-inorganic perovskite light-emitting device is manufactured in the same manner as in Preparation Example 5 using a solution in which a poly(4-vinylpyridinium tribromide) polymer of the following formula is dissolved as a material forming the passivation layer.

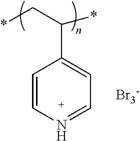

### <Preparation Examples 14 to 22> Preparation of a Perovskite Light-Emitting Device Including a Passivation Layer

Using the perovskite thin film prepared in Preparation Example 2, a perovskite light-emitting device is manufactured by performing the same method as in Preparation Examples 5 to 13, respectively.

### <Preparation Examples 23 to 31> Preparation of a Perovskite Light-Emitting Device Including a Passivation Layer

Using the perovskite thin film prepared in Preparation Example 3, a perovskite light-emitting device is manufactured by performing the same method as in Preparation Examples 5 to 13, respectively.

### <Preparation Examples 32 to 40> Preparation of a Perovskite Light-Emitting Device Including a Passivation Layer

Using the perovskite thin film prepared in Preparation Example 4, each is carried out in the same manner as in Preparation Examples 5 to 13 to manufacture a perovskite light-emitting device.

### <Experimental Example 1> Measurement of Photoluminescence Characteristics According to the Presence or Absence of a Passivation Layer Formed on a Perovskite Thin Film

In the perovskite light-emitting device according to the present inventive concept, in order to investigate the change in photoluminescence characteristics according to the presence or absence of a passivation layer composed of one or more compounds of Formulas 1 to 4 on the perovskite thin film.

Specifically, the photoluminescence characteristics before and after coating the TBMM thin film as a passivation layer on the perovskite thin film of Preparation Example 1 are measured with a photoluminescence meter, and the results are shown in FIG. 12.

FIG. 12 is a graph showing transient photoluminescence and steady-state photoluminescence before and after coating a TBMM thin film as a passivation layer on the perovskite thin film of metal halide perovskite nanocrystal particles.

As shown in FIG. 12, after coating the TBMM thin film on the perovskite thin film of the metal halide perovskite nanocrystal particles, the photoluminescence (PL) lifetime is prolonged, and the photoluminescence spectrum is shifted toward blue.

From this, it is confirmed that the TBMM thin film having an aryl halide substituent bonded to the benzene ring can be usefully used as a passivation layer by stabilizing the defects of the perovskite thin film.

### <Experimental Example 2> Measurement of Photoelectric Properties According to the Presence or Absence of a Passivation Layer on the Perovskite Thin Film

In the perovskite light-emitting device according to the present inventive concept, the following experiment is performed to investigate the change in photoelectric properties according to the presence or absence of a passivation layer composed of one or more compounds of Formulas 1 to 4 on the perovskite thin film.

Specifically, the X-ray photoelectron spectrum before and after coating the TBMM thin film as a passivation layer on the perovskite thin film of Preparation Example 1 is measured with an X-ray photoelectron spectroscopy, and the results are shown in FIG. 13.

FIG. 13 shows an X-ray photoelectron spectrum (XPS) before and after coating a TBMM thin film as a passivation layer on the perovskite thin firm of the metal halide perovskite nanocrystal particles.

As shown in FIG. 13, it can be seen that after coating the TBMM thin film, the binding energy of the peaks corresponding to Pb and Br increased. As a result, it can be confirmed that the TBMM material stabilizes the defects of the perovskite nanocrystal particles after coating.

### <Experimental Example 3> Measurement of the Current Density of Holes and Electrons According to the Presence or Absence of a Passivation Layer on the Perovskite Thin Film

In the perovskite light-emitting device according to the present inventive concept, the following experiment is performed to investigate the change in current density depending on the presence or absence of a passivation layer composed of one or more compounds of Formulas 1 to 4 on the perovskite thin film.

Specifically, in a hole-only device and an electron-only device, the current density before and after coating the TBMM thin film as a passivation layer on the perovskite thin film of Preparation Example 1 is measured. The results are shown in FIG. 14.

The left figure in FIG. 14 shows the current density according to the voltage of the hole-only device and the electron-only device before coating the TBMM thin film, and the right figure shows the current density according to the voltage of the hole-only device and the electron-only device after coating the TBMM thin film.

As shown in FIG. 14, before coating the TBMM thin film, the hole current density and the electron current density showed a sharp difference, but it is found that the hole current density and the electron current density became similar after coating the TBMM thin film. This confirms that the charge imbalance in the device is resolved.

Therefore, the TBMM thin film having an aryl halide substituent on the benzene ring can be usefully used as a passivation layer in a perovskite device by resolving the charge imbalance in the device including the perovskite thin film.

### <Experimental Example 4> Capacitance-Voltage Characteristic Measurement According to the Presence or Absence of a Passivation Layer on the Perovskite Thin Film

In the perovskite light-emitting device according to the present inventive concept, the following experiment is performed to investigate the change in capacitance depending on the presence or absence of a passivation layer composed of one or more compounds of Formulas 1 to 4 on the perovskite thin film.

Specifically, in the light-emitting device manufactured in Preparation Example 2, the capacitance-voltage characteristics are measured before and after coating the TBMM thin film as a passivation layer on the top of the light-emitting layer of the nanocrystal particles, and are shown in FIG. 15.

As shown in FIG. 15, after coating the TBMM thin film on the light-emitting layer, it is found that the maximum electric capacity is increased. This is because electron injection is prevented by the TBMM thin film. Through this, it can be seen that the TBMM thin film having an aryl halide substituent bonded to the benzene ring can be usefully used as a passivation layer in a perovskite device by eliminating charge imbalance in a device including a perovskite thin film functioning as a light-emitting layer.

### <Experimental Example 5> Measurement of Luminescence Efficiency Characteristics According to the Presence or Absence of a Passivation Layer Formed on a Perovskite Thin Film

In the perovskite light-emitting device according to the present inventive concept, the following experiment is performed to investigate the change in luminescence efficiency depending on the presence or absence of a passivation layer composed of one or more compounds of Formulas 1 to 4 on the perovskite thin film.

Specifically, in the light-emitting device fabricated in Preparation Example 2, the luminescence efficiency before and after coating the TBMM thin film as a passivation layer on the nanocrystal particle emission layer is measured and shown in FIG. 16.

As shown in FIG. 16, it can be seen that the luminescence efficiency and maximum luminance of the light-emitting diode are increased after coating the TBMM thin film as a passivation layer on the perovskite thin film. This is because the TBMM thin film solves the charge imbalance and alleviates the defects of the perovskite thin film.

As described above, in the perovskite light-emitting device according to the present inventive concept, defects of perovskite nanocrystal particles are alleviated by forming a passivation layer containing at least one compound of Formulas 1 to 4 on the perovskite thin film. In addition, since the charge imbalance in the device is resolved to improve luminescence efficiency and maximum luminance, it can be usefully used in place of the conventional perovskite device.

On the other hand, the embodiments of the present inventive concept disclosed in the specification and drawings are only presented specific examples to aid understanding and are not intended to limit the scope of the present inventive concept. In addition to the embodiments disclosed herein, it is apparent to those of ordinary skill in the art that other modified examples based on the technical idea of the present inventive concept may be implemented.

1. A perovskite light-emitting device comprising:
substrate;
a first electrode on the substrate;
a perovskite thin film positioned on the first electrode;
a passivation layer positioned on the perovskite thin film and having at least one compound of the following Chemical Formulas 1 to 4; and
a second electrode positioned on the passivation layer. 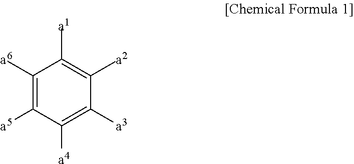
in Chemical Formula 1, a1 to a6 are H, CH₃, or CH₂X, wherein at least three of a1 to a6 are CH₂X, and X is a halogen element, 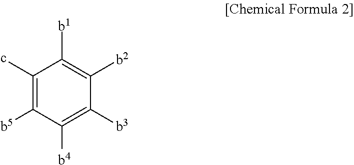
in Formula 2, b1 to b5 is halogen element, c is 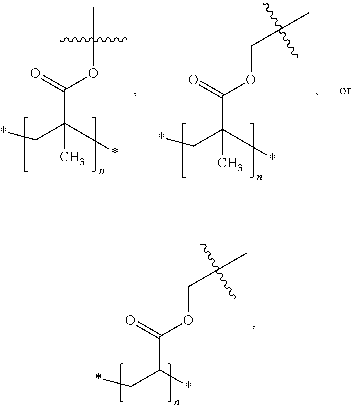
and n is integer 1 to 100, 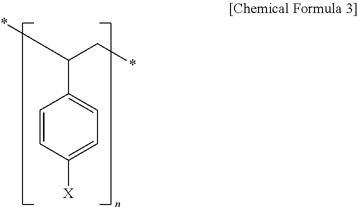
in Chemical Formula 3, X is halogen element, and n is integer 1 to 100, 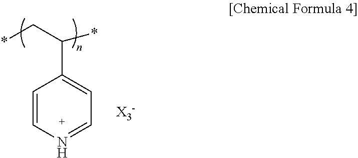
in Chemical Formula 4, X is halogen element, and n is integer 1 to 100.

2. The perovskite light-emitting device of claim 1, wherein the passivation layer has compounds at least one selected from the group of (1,3,5-tris(bromomethyl)benzene), 2,4,6-tris(bromomethyl)mesitylene (TBMM), 1,2,4,5-tetrakis(bromomethyl)benzene, hexabromomethyl)benzene, poly(pentabromophenyl methacrylate), poly(pentabromobenzyl methacrylate), poly(pentabromobenzyl acrylate), poly (4-bromostyrene) and poly(4-vinylpyridinium tribromide).

3. The perovskite light-emitting device of claim 1, wherein the passivation layer is a thickness of 1 nm to 100 nm.

4. The perovskite light-emitting device of claim 1, wherein the perovskite light-emitting device is a light-emitting diode, a light-emitting transistor, a laser, or a polarized light-emitting device.

5. The perovskite light-emitting device of claim 1, further comprises a hole injection layer or an electron transport layer between the first electrode and the perovskite thin film, or between the passivation layer and the second electrode.

6. The perovskite light-emitting device of claim 5, wherein the hole injection layer is positioned between the first electrode and the perovskite thin film, and the electron transport layer is positioned between the passivation layer and the second electrode.

7. A method of manufacturing a perovskite light-emitting device comprising:
forming a first electrode on a substrate;
forming a perovskite thin film on the first electrode;
forming a passivation layer having at least one compound of the following Chemical Formulas 1 to 4 on the perovskite thin film; and
a step of forming a second electrode on the passivation layer. 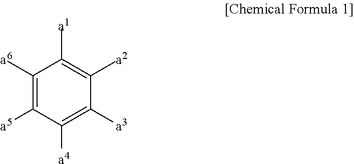
in Chemical Formula 1, a1 to a6 are H, CH₃, or CH₂X, wherein at least three of a1 to a6 are CH₂X, and X is a halogen element, 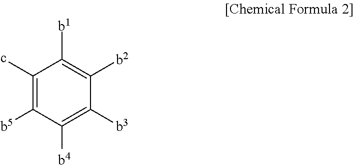
in Chemical Formula 2, b1 to b5 is halogen element, c is 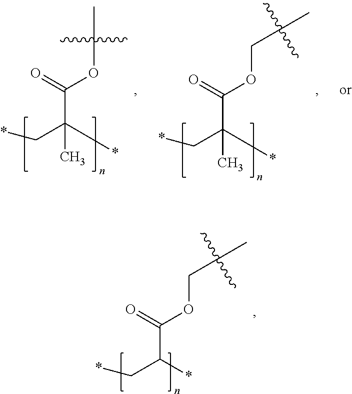
and n is integer 1 to 100, 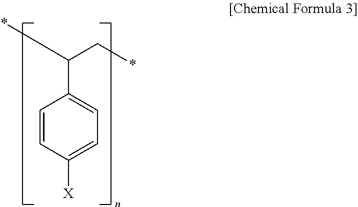
in Chemical Formula 3, X is halogen element, and n is integer 1 to 100, 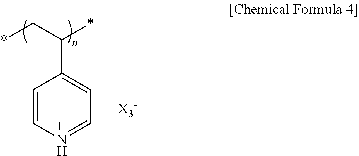
in Chemical Formula 4, X is halogen element, and n is integer 1 to 100.

8. A method of manufacturing a perovskite light-emitting device comprising:
forming a first electrode on a substrate;
forming a hole injection layer on the first electrode;
forming a perovskite thin film on the hole injection layer;
forming a passivation layer having at least one compound of the following Chemical Formulas 1 to 4 on the perovskite thin film; and
forming a second electrode on the passivation layer. 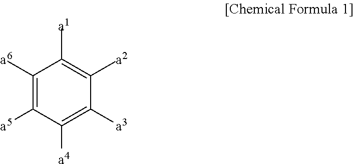
in Chemical Formula 1, a1 to a6 are H, CH₃, or CH₂X, wherein at least three of a1 to a6 are CH₂X, and X is a halogen element, 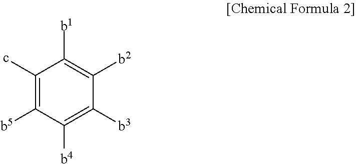
in Chemical Formula 2, b1 to b5 is halogen element, c is 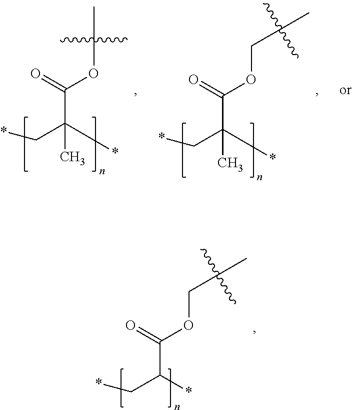
and n is integer 1 to 100, 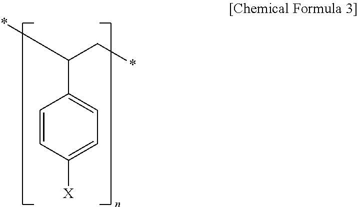
in Chemical Formula 3, X is halogen element, and n is integer 1 to 100, 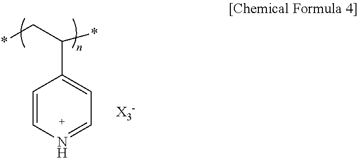
in Chemical Formula 4, X is halogen element, and n is integer 1 to 100.

9. The method of manufacturing the perovskite light-emitting device of claim 7, wherein the passivation layer has compound at least one selected from the group of (1,3,5-tris(bromomethyl)benzene), 2,4,6-tris(bromomethyl)mesitylene (TBMM), 1,2,4,5-Tetrakis(bromomethyl)benzene, hexakis(bromomethyl)benzene, poly(pentabromophenyl methacrylate), poly(pentabromobenzyl methacrylate), poly(pentabromobenzyl acrylate), poly(4-bromostyrene) and poly(4-vinylpyridinium tribromide).

10. The method of manufacturing the perovskite light-emitting device of claim 7,
wherein the passivation layer has a thickness of 1 nm to 100 nm.

11. The method of manufacturing the perovskite light-emitting device of claim 7,
wherein the passivation layer is formed by performing spin coating, bar coating, spray coating, slot die coating, gravure coating, blade coating, screen printing, nozzle printing, inkjet printing, electrohydrodynamic jet printing, electrospray or electrospinning.

12. The method of manufacturing the perovskite light-emitting device in claim 7, wherein the perovskite has a structure of ABX₃, A₂BX₄, A₃BX₅, A₄BX₆, ABX₄ or Aₙ₋₁PbₙX₃ₙ₊₁ (n is an integer between 2 and 6), wherein the A includes an organic ammonium ion, an organic amidinium ion, an organic phosphonium ion, an alkali metal ion, or a derivative thereof, the B includes a transition metal, a rare earth metal, an alkaline earth metal, an organic substance, an inorganic substance, ammonium, a derivative thereof, or a combination thereof, and the X is a halogen ion or a combination of different halogen ions.

13. The method of manufacturing the perovskite light-emitting device of claim 7, wherein the perovskite thin film is a bulk polycrystalline thin film or a thin film made of nanocrystal particles.

14. The method of manufacturing a perovskite light-emitting device of claim 13, wherein the nanocrystal particles have a core-shell structure or a structure having a gradient composition.
